(19) United States
(12) Patent Application Publication
(10) Pub. No.: US 2024/0284776 A1
(43) Pub. Date: Aug. 22, 2024

(54) Organic Light-Emitting Diode

(71) Applicant: LG Display Co., Ltd., Seoul (KR)

(72) Inventors: Sangbeom Kim, Seoul (KR); Seongsu Jeon, Seoul (KR); Youngjun Yu, Seoul (KR); Seonkeun Yoo, Suwon-si, Gyeonggi-do (KR); Kusun Choung, Seoul (KR)

(21) Appl. No.: 18/400,336

(22) Filed: Dec. 29, 2023

(30) Foreign Application Priority Data
Jan. 31, 2023 (KR) 10-2023-0012863

(51) Int. Cl. H10K 85/30; C09K 11/02; C09K 11/06

(52) U.S. Cl. CPC H10K 85/342; C09K 11/02; C09K 11/06; C09K 2211/1007; C09K 2211/1029; C09K 2211/1088; C09K 2211/185; H10K 50/10; H10K 2101/10; H10K 2101/30; H10K 2101/90; H10K 2102/351

(57) ABSTRACT

Disclosed are a structure of an organic light-emitting diode capable of lowering an operation voltage, and improving luminous efficacy and lifetime of an organic light-emitting diode, and a material thereof.

### CROSS-REFERENCE TO RELATED APPLICATION

This application claims priority to and benefit of Republic of Korea Patent Application No. 10-2023-0012863 filed on Jan. 31, 2023, which is hereby incorporated by reference in its entirety.

### BACKGROUND

### Field

The present disclosure relates to an organic light-emitting diode, and more particularly, to a host material of a phosphorescent light-emitting layer capable of improving performance of an organic light-emitting diode, and an organic light-emitting diode including the same.

### Description of Related Art

As a display device is applied to various fields, interest with the display device is increasing. One of the display devices is an organic light-emitting display device including an organic light-emitting diode (OLED) which is rapidly developing.

In the organic light-emitting diode, when electric charges are injected into a light-emissive layer formed between a positive electrode and a negative electrode, an electron and a hole are recombined with each other in the light-emissive layer to generate an exciton and thus energy of the exciton is converted to light. Thus, the organic light-emitting diode emits the light. Compared to conventional display devices, the organic light-emitting diode may operate at a low voltage, consume relatively little power, render excellent colors, and may be used in a variety of ways because a flexible substrate may be applied thereto. Further, a size of the organic light-emitting diode may be freely adjustable.

The organic light-emitting diode (OLED) has superior viewing angle and contrast ratio compared to a liquid crystal display (LCD), and is lightweight and is ultra-thin because the OLED does not require a backlight. The organic light-emitting diode includes a plurality of organic layers between a negative electrode (electron injection electrode; cathode) and a positive electrode (hole injection electrode; anode). The plurality of organic layers may include a hole injection layer, a hole transfer layer, a hole transfer auxiliary layer, an electron blocking layer, a light-emissive layer, and an electron transfer layer, etc.

In this organic light-emitting diode structure, when a voltage is applied across the two electrodes, electrons and holes are injected from the negative and positive electrodes, respectively, into the light-emissive layer and thus excitons are generated in the light-emissive layer and then fall to a ground state to emit light.

Organic materials used in the organic light-emitting diode may be largely classified into light-emitting materials and charge-transferring materials. The light-emitting material is an important factor determining luminous efficiency of the organic light-emitting diode. The luminescent material must have high quantum efficiency, excellent electron and hole mobility, and must exist uniformly and stably in the light-emissive layer. The light-emitting materials may be classified into light-emitting materials emitting light of blue, red, and green colors based on colors of the light. A color-generating material may include a host and dopants to increase the color purity and luminous efficiency through energy transfer.

When the fluorescent material is used, singlets as about 25% of excitons generated in the light-emissive layer are used to emit light, while most of triplets as 75% of the excitons generated in the light-emissive layer are dissipated as heat. However, when the phosphorescent material is used, singlets and triplets are used to emit light.

In addition, in the organic light-emitting diode including the phosphorescent light-emitting layer, hole accumulation phenomenon due to leakage of holes that do not involve in generating the excitons at an interface between the light-emitting layer (EML) and the electron transfer layer (ETL) and inside the light-emitting layer (EML). This causes degradation of the interface between the light-emitting layer (EML) and the electron transfer layer (ETL), and the inside of the light emitting layer (EML). As a result, there occurs problems of increasing the operation voltage of the organic light-emitting diode and reducing the lifetime of the organic light-emitting diode.

Therefore, research and development on a structure of the organic light-emitting diode which may solve the above limitations and problems, and an organic material capable of realizing the organic light-emitting diode are continuously required.

### SUMMARY

A purpose of the present disclosure is to provide a structure of an organic light-emitting diode capable of lowering the operation voltage of the organic light-emitting diode, and improving light emission efficiency, and a lifetime of the organic light-emitting diode.

Specifically, a purpose of the present disclosure is to provide a structure of an organic light-emitting diode which may solve the hole accumulation phenomenon due to the hole leakage occurring at the interface between the light-emitting layer and the electron transfer layer and inside the light-emitting layer to cause the decrease in the lifespan of the organic light-emitting diode, and at the same time, which may increase the luminous efficiency, and to provide a material of an organic layer capable of realizing the organic light-emitting diode.

Purposes of the present disclosure are not limited to the above-mentioned purpose. Other purposes and advantages of the present disclosure that are not mentioned may be understood based on following descriptions, and may be more clearly understood based on embodiments of the present disclosure. Further, it will be easily understood that the purposes and advantages of the present disclosure may be realized using means shown in the claims and combinations thereof.

In order to achieve the above purpose, a first aspect of the present disclosure may provide an organic light-emitting diode comprising: a first electrode: a second electrode facing the first electrode; and an organic layer disposed between the first electrode and the second electrode, wherein the organic layer includes a hole transfer layer, a light-emitting layer, a hole scavenger layer, and an electron transfer layer, wherein the hole scavenger layer is disposed between the light-emitting layer and the electron transfer layer, wherein the light-emitting layer includes a first host, a second host, and a dopant, wherein the electron transfer layer includes an electron transfer material, wherein the hole scavenger layer includes a hole scavenger material, wherein a following condition (1) is satisfied:

$$\vert {HOMO}_{( HSL )} \vert \leq \vert {HOMO}_{( HOST - 1 )} \vert \leq \vert {HOMO}_{( HOST - 2 )} \vert \leq \vert {HOMO}_{( ETL )} \vert \qquad condition ( 1 )$$

where in the condition (1), |HOMO_{(HSL)}| denotes an absolute value of a HOMO (Highest Occupied Molecular Orbital) energy level of the hole scavenger material, |HOMO_{(ETL)}| denotes an absolute value of a HOMO energy level of the electron transfer material, |HOMO_{(HOST-1)}| denotes an absolute value of a HOMO energy level of the first host of the light-emitting layer, and |HOMO_{(HOST-2)}| denotes an absolute value of a HOMO energy level of the second host of the light-emitting layer.

According to the second aspect of the present disclosure, an organic light-emitting display device including the organic light-emitting diode according to the first aspect of the present disclosure may be provided.

In the organic light-emitting diode of the present disclosure, the hole scavenger layer (HSL) may be disposed between the light-emitting layer and the electron transfer layer, and may capture leaked holes. Thus, the performance degradation phenomenon, and in particular, the problem of the reduced lifespan as caused by the hole accumulation phenomenon due to the hole leakage occurring at the interface between the light-emitting layer and the electron transfer layer and inside the electron transfer layer may be removed to achieve the low power consumption of the organic light-emitting diode.

In the organic light-emitting diode of the present disclosure, the hole scavenger layer may be disposed at the interface between the light-emitting layer and the electron transfer layer to solve the hole accumulation phenomenon caused by the hole leakage, thereby improving the lifetime of the organic light-emitting diode. At the same time, the hole scavenger layer may be disposed adjacent to the light-emitting layer to sufficiently realize triplet exciton confinement to improve the efficiency of the organic light-emitting diode. In addition, at the interface between the light-emitting layer and the hole scavenger layer, the hole scavenger material converts non-radiative decay into radiative decay, thereby reducing thermal energy generated during light emission, and thus increasing the lifetime and efficiency of organic light-emitting diode.

Effects of the present disclosure are not limited to the above-mentioned effects, and other effects as not mentioned will be clearly understood by those skilled in the art from following descriptions.

### BRIEF DESCRIPTION OF DRAWINGS

FIG. 1 is a schematic cross-sectional view of an organic light-emitting diode according to an embodiment of the present disclosure.

FIG. 2 is a cross-sectional view schematically showing an organic light-emitting diode having a tandem structure having two light-emitting stacks according to an embodiment of the present disclosure.

FIG. 3 is a cross-sectional view schematically showing an organic light-emitting diode of a tandem structure having three light-emitting stacks according to an embodiment of the present disclosure.

FIG. 4 is a cross-sectional view schematically illustrating an organic light-emitting display device including an organic light-emitting diode according to an embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims. The same reference numbers in different drawings represent the same or similar elements.

Further, descriptions and details of well-known steps and elements are omitted for simplicity of the description. Furthermore, in the following detailed description of the present disclosure, numerous specific details are set forth in order to provide a thorough understanding of the present disclosure.

As used herein, the singular constitutes “a” and “an” are intended to include the plural constitutes as well, unless the context clearly indicates otherwise. It will be further understood that the terms “have”, “having”, “comprise”, “comprising”, “include”, and “including” when used herein, specify the presence of the stated features, integers, operations, elements, and/or components, but do not preclude the presence or addition of one or more other features, integers, operations, elements, components, and/or portions thereof.

In interpreting a numerical value, the value is interpreted as including an error range unless there is separate explicit description thereof.

In addition, it will also be understood that when a first element or layer is referred to as being present “on top of (or under)” a second element or layer, the first element may be disposed directly on top of (or under) the second element or may be disposed indirectly on top of (or under) the second element with a third element or layer being disposed between the first and second elements or layers.

As used herein, the term “halo” or “halogen” includes fluorine, chlorine, bromine and iodine.

As used herein, the term “alkyl group” refers to both linear alkyl radicals and branched alkyl radicals. Unless otherwise specified, the alkyl group contains 1 to 20 carbon atoms, and includes methyl, ethyl, propyl, isopropyl, butyl, isobutyl, tert-butyl, etc. Further, the alkyl group may be optionally substituted.

As used herein, the term “cycloalkyl group” refers to a cyclic alkyl radical. Unless otherwise specified, the cycloalkyl group contains 3 to 20 carbon atoms, and includes cyclopropyl, cyclopentyl, cyclohexyl, and the like. Further, the cycloalkyl group may be optionally substituted.

As used herein, the term “alkenyl group” refers to both linear alkene radicals and branched alkene radicals. Unless otherwise specified, the alkenyl group contains 2 to 20 carbon atoms. Additionally, the alkenyl group may be optionally substituted.

As used herein, the term “alkynyl group” refers to both linear alkyne radicals and branched alkyne radicals. Unless otherwise specified, the alkynyl group contains 2 to 20 carbon atoms. Additionally, the alkynyl group may be optionally substituted.

The terms “aralkyl group” and “arylalkyl group” as used herein are used interchangeably with each other and refer to an alkyl group having an aromatic group as a substituent. Further, the alkylaryl group may be optionally substituted.

The terms “aryl group” and “aromatic group” as used herein are used in the same meaning. The aryl group includes both a monocyclic group and a polycyclic group. The polycyclic group may include a “fused ring” in which two or more rings are fused with each other such that two carbons are common to two adjacent rings. Unless otherwise specified, the aryl group contains 6 to 60 carbon atoms. Further, the aryl group may be optionally substituted.

The term “heterocyclic group” as used herein means that at least one of carbon atoms constituting an aryl group, a cycloalkyl group, or an aralkyl group (arylalkyl group) is substituted with a heteroatom such as oxygen (O), nitrogen (N), sulfur (S), etc. Further, the heterocyclic group may be optionally substituted.

The term “carbon ring” as used herein may be used as a term including both “cycloalkyl group” as an alicyclic group and “aryl group” an aromatic group unless otherwise specified.

The terms “heteroalkyl group” and “heteroalkenyl group” as used herein mean that at least one of carbon atoms constituting the group is substituted with a heteroatom such as oxygen (O), nitrogen (N), or sulfur (S). In addition, the heteroalkyl group and the heteroalkenyl group may be optionally substituted.

As used herein, the term “substituted” means that a substituent other than hydrogen (H) binds to corresponding carbon.

Unless specifically limited herein, the substituent may be deuterium, halogen, an alkyl group, a heteroalkyl group, an alkoxy group, an aryloxy group, an alkynyl group, an aryl group, a heteroaryl group, an acyl group, a carbonyl group, a carboxylic acid group, a nitrile group, a cyano group, an amino group, an alkylsilyl group, an arylsilyl group, a sulfonyl group, a phosphino group, and combinations thereof.

Subjects and substituents as defined in the present disclosure may be the same as or different from each other unless otherwise specified.

Even when “unsubstituted” is not specified herein, this may be interpreted as presence of hydrogen basically binding to carbon unless a substituent binds thereto.

In the present disclosure, each of a highest occupied molecular orbital (HOMO) energy level (eV) and a lowest unoccupied molecular orbital (LUMO) energy level (eV) is based on a cyclic voltammetry (CV) measurement scheme, and is calculated, specifically, based on a following condition and a following equation:

HOMO and LUMO Energy Levels Measurement Scheme (CV Scheme)

| Solution | Standard | Electrolyte | | | Standard | |
|---|---|---|---|---|---|---|
| concentration | electrode | Solute | Solvent | Concentration | material | Energy level equation |
| 1 mM | Ag/AgCl | Bu₄NPF₆ | DMF | 0.1M | Ferrocene | E = −4.8 − (Eₒₓ − E_{fc})(eV) |
| | | | | | | Eₒₓ: oxidation on-set value |
| | | | | | | E_{fc}: ferrocene energy |

In the present disclosure, a triplet energy (T₁) is obtained as follows: photoluminescence of a solution in which a material to be measured is dissolved in 2-methyl THF solvent is measured in an environment of 77 K to obtain a PL spectrum, and an energy level (unit: eV) of a first peak of the obtained PL spectrum is converted to the triplet energy.

Hereinafter, a structure of an organic light-emitting diode according to the present disclosure will be described in detail.

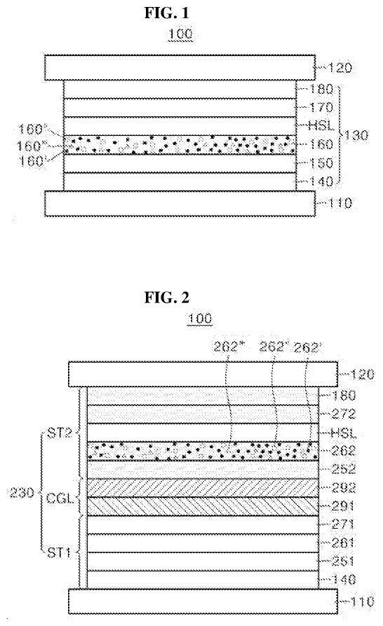

Referring to FIG. 1 of the present disclosure, an organic light-emitting device 100 according to an embodiment of the present disclosure may include a first electrode 110, a second electrode 120 facing the first electrode 110, and an organic layer 130 disposed between the first electrode 110 and the second electrode 120. The organic layer 130 may be embodied as a stack formed by sequentially stacking a hole injection layer (HIL) 140, a hole transfer layer (HTL) 150, a light-emitting layer (EML) 160, a hole scavenger layer (HSL), an electron transfer layer (ETL) 170 and an electron injection layer (EIL) 180 on the first electrode 110. The hole transfer layer 150, the light-emitting layer 160, the hole scavenger layer (HSL), and the electron transfer layer 170 are disposed sequentially in a direction from the first electrode 110 to the second electrode 120. The second electrode 120 may be formed on the electron injection layer 180, and optionally, a protective film (not shown) may be formed on the second electrode 120. In particular, based on a result of intensive research by the present inventors, it was identified that the hole scavenger layer (HSL) additionally disposed between the light-emitting layer 160 and the electron transfer layer 170 may capture the leaked hole to improve the degradation phenomenon caused by the hole accumulation due to the hole leakage occurring at the interface between the light-emitting layer and the electron transfer layer and inside the electron transfer layer. In this way, the present disclosure has been completed.

According to one aspect of the present disclosure, the light-emitting layer 160 may be a red light-emitting layer.

The light-emitting layer 160 is characterized by including two types of hosts in one embodiment. A first host 160′ refers to a hole type host that mainly serves to receive holes transferred/injected from the hole transfer layer and to supply the same to the light-emitting layer. A second host 160″ refers to an electron type host which mainly serves to receive electrons transferred/injected from the electron transfer layer and to supply the same to the light-emitting layer.

In order that the main role of each of the first host 160′ and the second host 160″ is efficiently performed to achieve the purpose of the present disclosure, the energy levels of the two types of hosts may satisfy a following relationship (1):

$$\vert {HOMO}_{( HOST - 1 )} \vert \leq \vert {HOMO}_{( HOST - 2 )} \vert \qquad Relationship ( 1 )$$

In one embodiment, the hole scavenger layer satisfies a following condition (1), and the following condition (1) includes a condition of the relationship (1). Further, the HOMO energy level of the electron transfer layer 170 is required to be equal to or greater than the HOMO energy level of the electron transfer type host of the light-emitting layer in order to implement the light emitting mechanism.

$$\vert {HOMO}_{( HSL )} \vert \leq \vert {HOMO}_{( HOST - 1 )} \vert \leq \vert {HOMO}_{( HOST - 2 )} \vert \leq \vert {HOMO}_{( ETL )} \vert \qquad Condition ( 1 )$$

In the condition (1), HOMO_{(HSL)} denotes a highest occupied molecular orbital (HOMO) energy level of the hole scavenger material. HOMO_{(ETL)} denotes a HOMO energy level of the electron transfer material. HOMO_{(HOST-1)} denotes a HOMO energy level of the first host of the light-emitting layer. HOMO_{(HOST-2)} denotes a HOMO energy level of the second host of the light-emitting layer.

Therefore, the condition (1) requires that the absolute value of the HOMO energy level of the hole scavenger material is equal to or smaller than the absolute value of the HOMO energy level of the first host 160′ which is a hole transfer type host of the light-emitting layer 160. When the above condition (1) is not satisfied, the hole in the light-emitting layer 160 does not combine with an electron and thus moves to the electron transfer layer 170, thereby reducing the efficiency of the organic light-emitting diode.

According to one embodiment of the present disclosure, the |HOMO_{(HOST-1)}| may be in a range of 5.0 to 6.0 (eV), and the |HOMO_{(HOST-2)}| may be in a range of 5.2 to 6.2 (eV).

According to one embodiment of the present disclosure, the |HOMO_{(HSL)}| may be in a range of 4.5 to 5.5 (eV).

According to one embodiment of the present disclosure, the |HOMO_{(ETL)}| may be in a range of 5.4 to 6.4 (eV).

According to one embodiment of the present disclosure, a following condition (2) may be further satisfied.

$$△ ( \vert {HOMO}_{( HOST - 1 )} \vert - \vert {HOMO}_{( HSL )} \vert ) \geq 0.15 ( eV ) \qquad Condition ( 2 )$$

The condition (2) means that a difference between the absolute value of the HOMO energy level of the hole scavenger material and the absolute value of the HOMO energy level of the first host 160′ as the hole transfer type host of the light-emitting layer 160 is equal to or greater than 0.15 (eV). In one embodiment, the difference is equal to or greater than 0.20 (eV). When the condition (2) is not satisfied, the hole scavenger material cannot sufficiently trap the holes, such that it may be difficult for the hole scavenger layer to achieve the increase in the lifetime of the organic light-emitting diode.

According to one embodiment of the present disclosure, a thickness of the hole scavenger layer (HSL) may be greater than 0 Å and smaller than 30 Å, more specifically, may be in a range of 3 Å to 28 Å, and even more specifically, 5 Å to 25 Å. When the thickness of the hole scavenger layer (HSL) exceeds 30 Å, the hole scavenger layer (HSL) interferes with the movement of the electrons, resulting in increase in the operation voltage and decrease in the lifetime of the light-emitting diode.

According to one embodiment of the present disclosure, a following condition (3) may be further satisfied:

$$\vert {T}_{1 ( DOP )} \vert \leq \vert {T}_{1 ( HSL )} \vert \qquad condition ( 3 )$$

In the condition (3), T_{1 (DOP)} denotes a triplet energy level of the dopant of the light-emitting layer. T_{1 (HSL)} denotes a triplet energy level of the hole scavenger material.

Since the organic light-emitting diode of the present disclosure has a structure in which the light-emitting layer and the hole scavenger layer are directly stacked on top of each other, the relationship between the triplet energy of the dopant of the light-emitting layer and the triplet energy of the hole scavenger material at the interface of the light-emitting layer and the hole scavenger layer may satisfy condition (3), thereby increasing the efficiency of the light-emitting diode while improving the lifespan thereof.

When the above condition (3) is not satisfied and thus, the triplet energy level of the hole scavenger material is lower than the triplet energy level of the dopant of the light-emitting layer, the triplet exciton confinement in the light-emitting layer does not sufficiently occur, resulting in the decrease in the efficiency of the organic light-emitting diode. The triplet energy level of the hole scavenger material is preferably higher than that of the dopant of the light-emitting layer.

According to one embodiment of the present disclosure, the triplet energy level of the hole scavenger material is smaller than or equal to “|T_{1(DOP)}|+0.3 (eV)”. This is because when the difference between the triplet energy level of the hole scavenger material and that of the dopant becomes too large, the effect of increasing the efficiency may decrease.

According to one embodiment of the present disclosure, |T_{1(DOP)}| is preferably in a range of 1.8 to 2.6 (eV), more specifically, in a range of 1.9 to 2.5 (eV).

The hole scavenger material of the present disclosure may be used without particular limitation thereto as long as the hole scavenger material satisfies the above conditions. For example, according to one embodiment of the present disclosure, the hole scavenger material of the present disclosure may include an iridium complex compound as an organometallic compound represented by a following Chemical Formula 1. However, the present disclosure is not limited thereto:

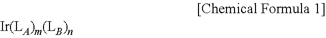

In the Chemical Formula 1, L_{A} may be a main ligand represented by at least one selected from a group consisting of following Chemical Formula 2-1, Chemical Formula 2-2 and Chemical Formula 2-3. L_{B} may be an auxiliary ligand represented by a following Chemical Formula 3. A dotted line on a 2-phenylpyridine moiety of each of the main ligand and the auxiliary ligand indicates that each of the main ligand and the auxiliary ligand binds to a central metal Ir (iridium).

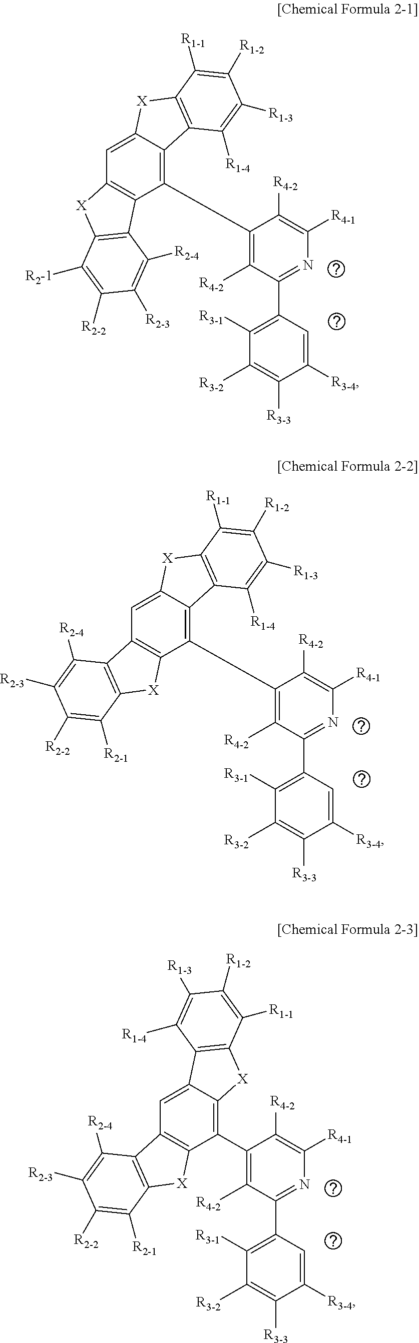

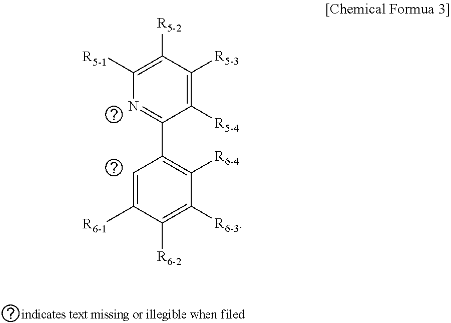

In each of Chemical Formulas 2-1 to 2-3, each X may independently represent one selected from a group consisting of O (oxygen), S (sulfur), NR₇ and C(R₈)(R₉). In one embodiment, each X may independently represent one of oxygen, sulfur or C(R₈)(R₉).

Each of R₇, R₈ and R₉ may independently represent one selected from a group consisting of C1 to C30 alkyl, C3 to C30 cycloalkyl, C1 to C30 heteroalkyl, C7 to C30 arylalkyl, C1 to C30 alkoxy, C6 to C30 aryloxy, amino, silyl, C2 to C30 alkenyl, C3 to C30 cycloalkenyl, C3 to C30 heteroalkenyl, C2 to C30 alkynyl, C6 to C40 aryl, C3 to C40 heteroaryl, and combinations thereof. Each of R₇, R₈ and R₉ may preferably be a C1 to C30 alkyl group, more specifically, be a C1 to C5 linear alkyl group.

Each of R₁₋₁, R₁₋₂, R₁₋₃, R₁₋₄, R₂₋₁, R₂₋₂, R₂₋₃, R₂₋₄, R₃₋₁, R₃₋₂, R₃₋₃, R₃₋₄, R₄₋₁, R₄₋₂ and R₄₋₃ may independently represent one selected from a group consisting of hydrogen, deuterium, halide, C1 to C30 alkyl, C3 to C30 cycloalkyl, C1 to C30 heteroalkyl, C7 to C30 arylalkyl, C1 to C30 alkoxy, C6 to C30 aryloxy, amino, silyl, C2 to C30 alkenyl, C3 to C30 cycloalkenyl, C3 to C30 heteroalkenyl, C2 to C30 alkynyl, C6 to C40 aryl, C3 to C40 heteroaryl, acyl, carbonyl, carboxylic acid, ester, nitrile, isonitrile, sulfanyl, sulfinyl, sulfonyl, phosphino, and combinations thereof. Preferably, each of R₁₋₁, R₁₋₂, R₁₋₃, R₁₋₄, R₂₋₁, R₂₋₂, R₂₋₃, R₂₋₄, R₃₋₁, R₃₋₂, R₃₋₃, R₃₋₄, R₄₋₁, R₄₋₂ and R₄₋₃ may be one of hydrogen, deuterium, or C1 to C5 linear alkyl group, and more specifically, one of hydrogen or deuterium.

Optionally, two adjacent substituents of R₁₋₁, R₁₋₂, R₁₋₃, R₁₋₄, R₂₋₁, R₂₋₂, R₂₋₃, R₂₋₄, R₃₋₁, R₃₋₂, R₃₋₃, R₃₋₄, R₄₋₁, R₄₋₂ and R₄₋₃ may be connected to each other to one ring structure selected from a group consisting of a substituted or unsubstituted C3 to C20 cycloalkyl group, a substituted or unsubstituted C2 to C20 heterocycloalkyl group, a substituted or unsubstituted C7 to C20 arylalkyl group, a substituted or unsubstituted C2 to C20 heteroarylalkyl group, a substituted or unsubstituted C3 to C20 cycloalkenyl group, a substituted or unsubstituted C6 to C30 aryl group, and a substituted or unsubstituted C3 to C30 heteroaryl group. However, according to one aspect of the present disclosure, two adjacent substituents of R₁₋₁, R₁₋₂, R₁₋₃, R₁₋₄, R₂₋₁, R₂₋₂, R₂₋₃, R₂₋₄, R₃₋₁, R₃₋₂, R₃₋₃, R₃₋₄, R₄₋₁, R₄₋₂ and R₄₋₃ may not be connected to each other.

In the Chemical Formula 3, each of R₅₋₁, R₅₋₂, R₅₋₃, R₅₋₄, R₆₋₁, R₆₋₂, R₆₋₃ and R₆₋₄ may independently represent one selected from a group consisting of hydrogen, deuterium, C1 to C5 linear alkyl group, and C1 to C5 branched alkyl group. Optionally, the C1 to C5 linear alkyl group or the C1 to C5 branched alkyl group selected as R₅₋₁, R₅₋₂, R₅₋₃, R₅₋₄, R₆₋₁, R₆₋₂, R₆₋₃ or R₆₋₄ may be unsubstituted or substituted with at least one selected from deuterium and a halogen element.

Optionally, two adjacent substituents of R₅₋₁, R₅₋₂, R₅₋₃, R₅₋₄, R₆₋₁, R₆₋₂, R₆₋₃ and R₆₋₄ may be connected to each other to form one ring structure selected from a group consisting of a substituted or unsubstituted C3 to C20 cycloalkyl group, a substituted or unsubstituted C2 to C20 heterocycloalkyl group, a substituted or unsubstituted C7 to C20 arylalkyl group, a substituted or unsubstituted C2 to C20 heteroarylalkyl group, a substituted or unsubstituted C3 to C20 cycloalkenyl group, a substituted or unsubstituted C6 to C30 aryl group, and a substituted or unsubstituted C3 to C30 heteroaryl group. However, according to one aspect of the present disclosure, the two adjacent substituents of R₅₋₁, R₅₋₂, R₅₋₃, R₅₋₄, R₆₋₁, R₆₋₂, R₆₋₃ and R₆₋₄ may not be connected to each other.

m may be 1, 2 or 3, n may be 0, 1 or 2, and a sum of m and n may be 3. According to one implementation of the present disclosure, the compound represented by the above Chemical Formula 1 may have a heteroleptic structure or a homoleptic structure. For example, the compound represented by the above Chemical Formula 1 may have a heteroleptic structure where m is 1 and n is 2 in the Chemical Formula 1. For example, the compound represented by the above Chemical Formula 1 may have a heteroleptic structure where m is 2 and n is 1 in the Chemical Formula 1. For example, the compound represented by the above Chemical Formula 1 may have a homoleptic structure where m is 3 and n is 0 in the Chemical Formula 1. Preferably, the compound represented by the above Chemical Formula 1 may have the heteroleptic structure where m is 1 or 2 in the Chemical Formula 1.

A specific example of the compound represented by the Chemical Formula 1 of the present disclosure may be at least one selected from a group consisting of following Compounds 1 to 38. However, the specific example of the compound represented by the Chemical Formula 1 of the present disclosure is not limited thereto as long as it meets the above definition of the Chemical Formula 1:

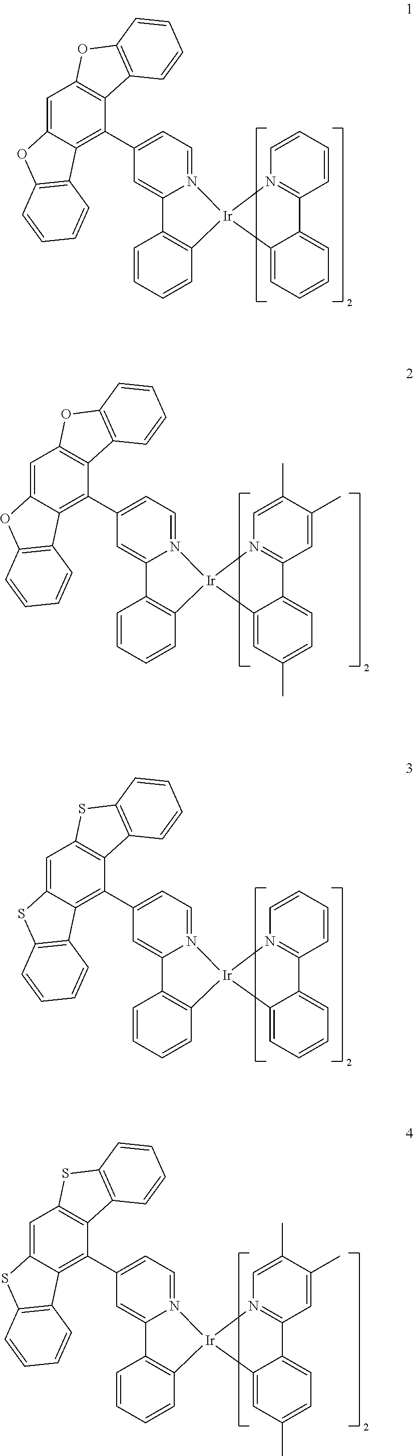

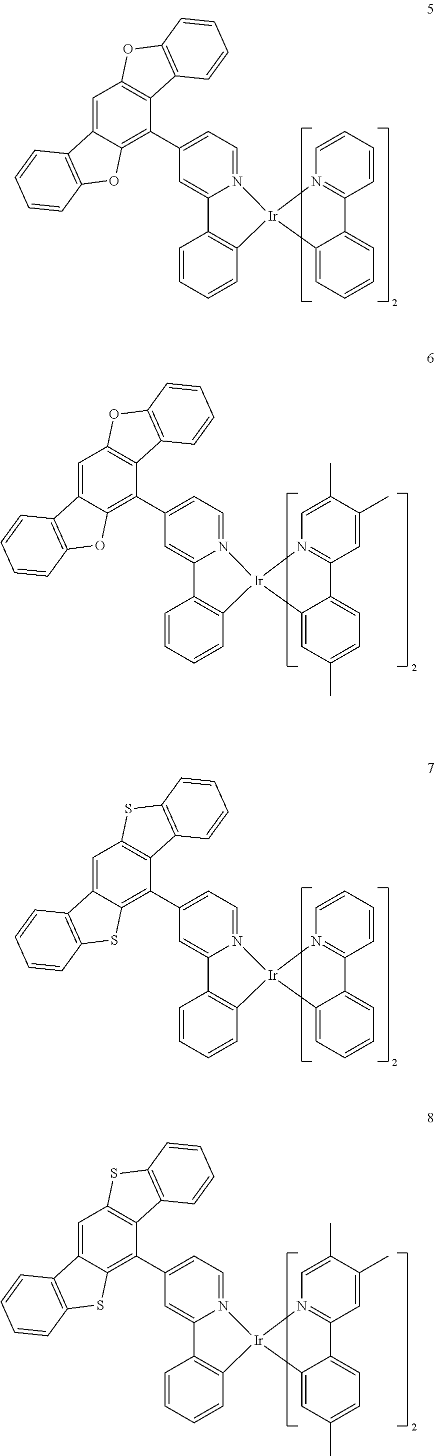

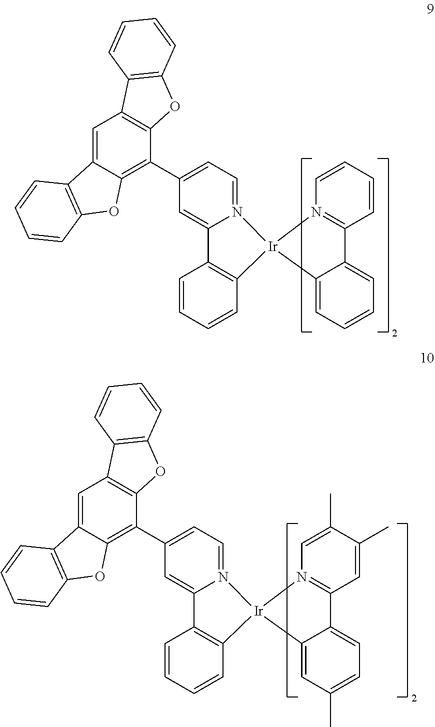

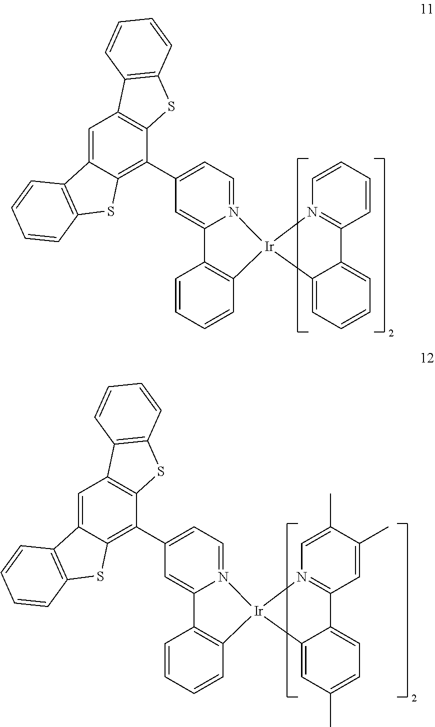

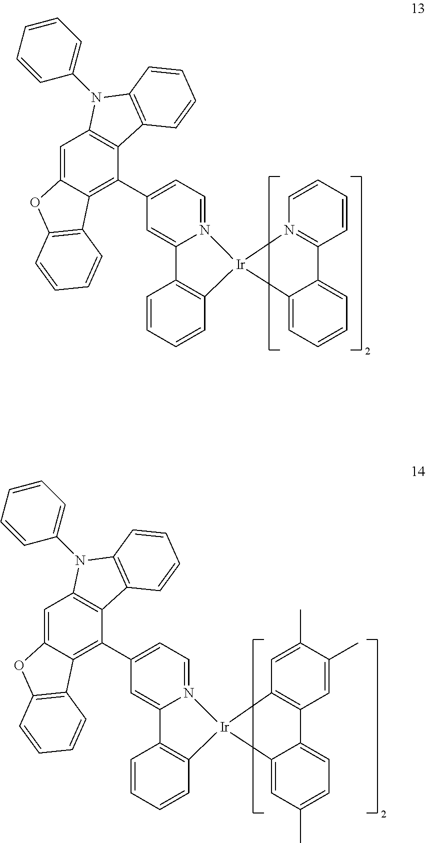

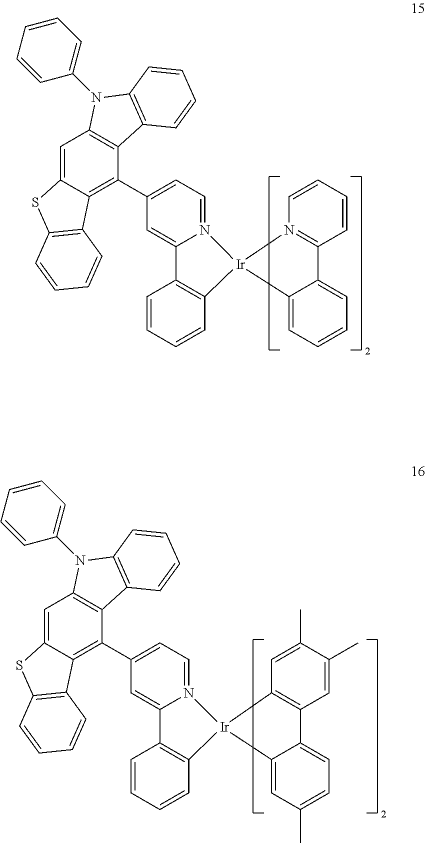

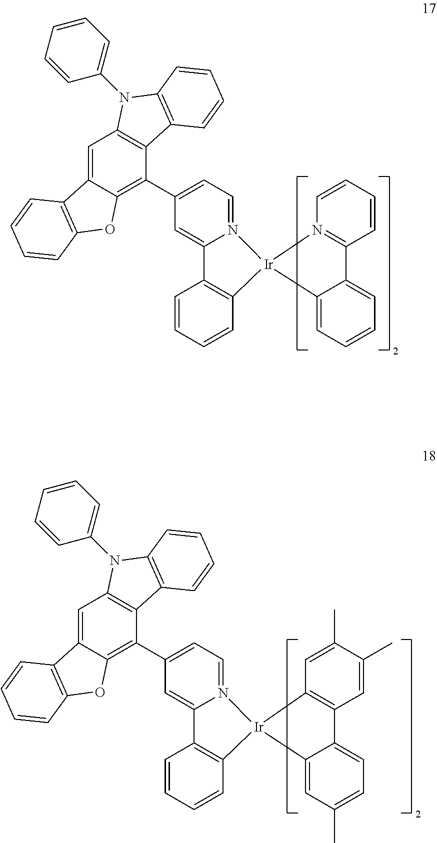

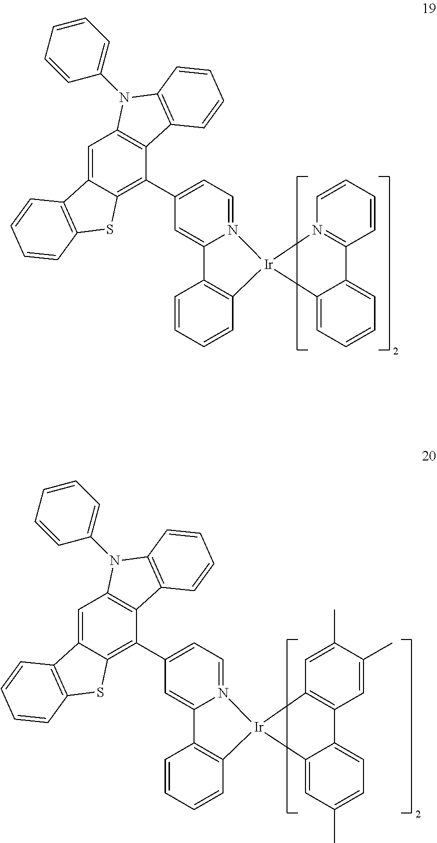

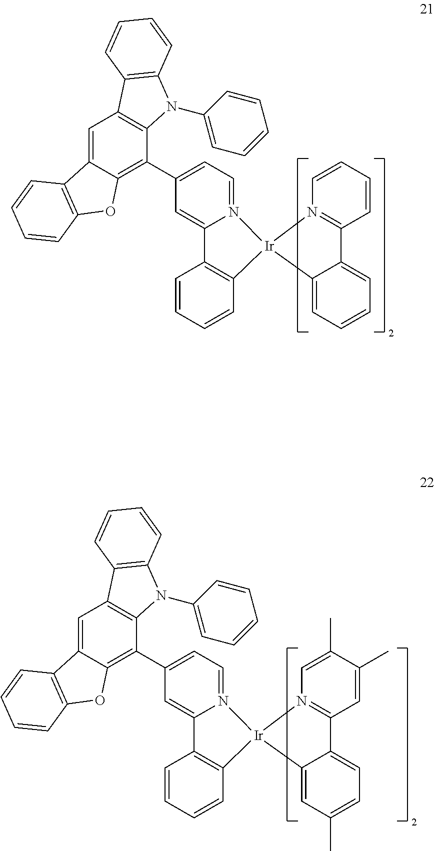

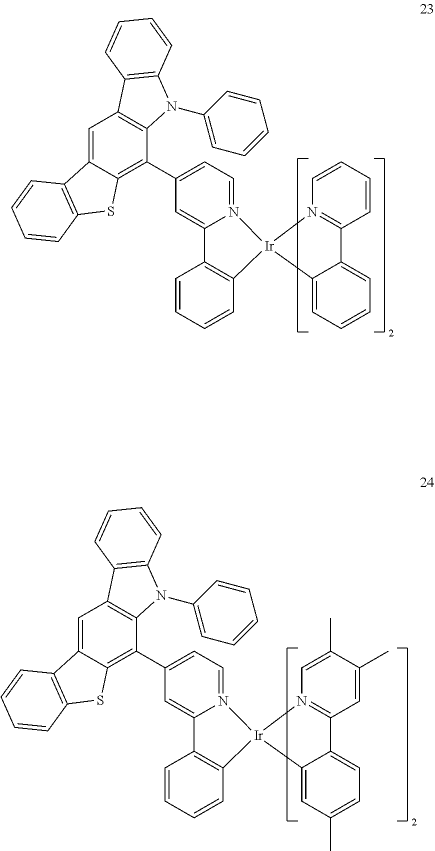

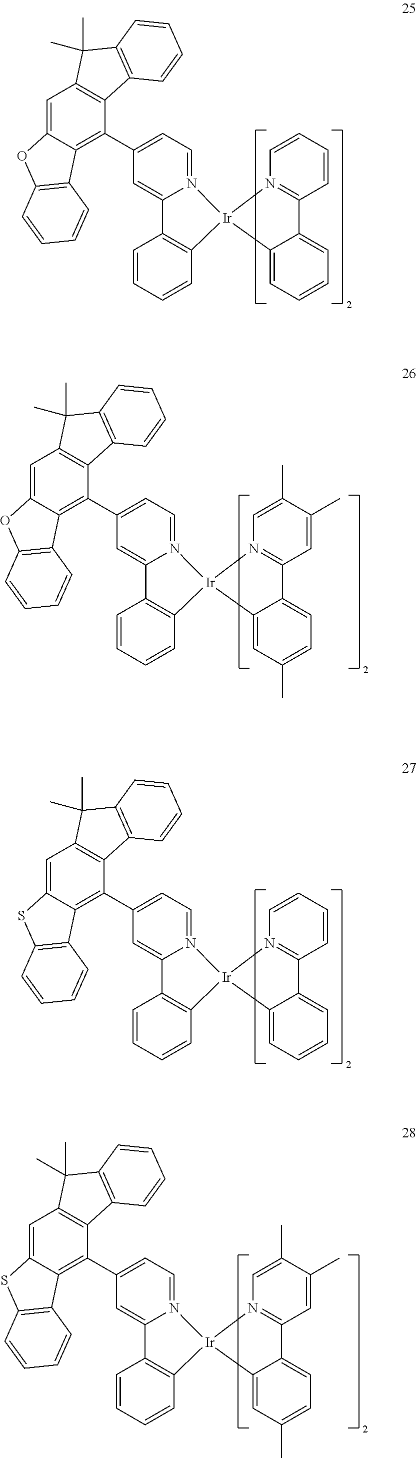

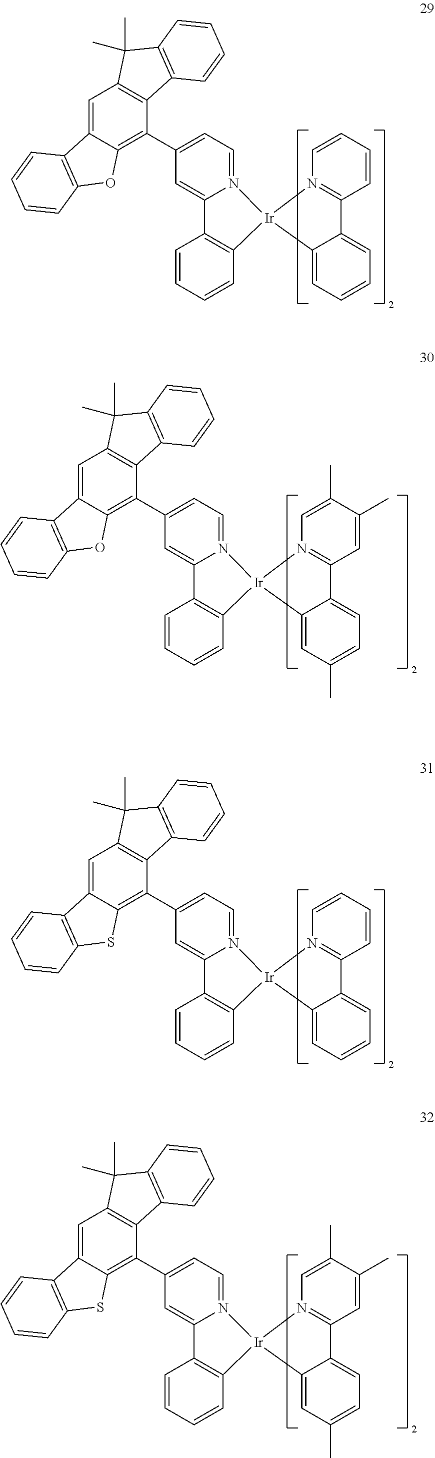

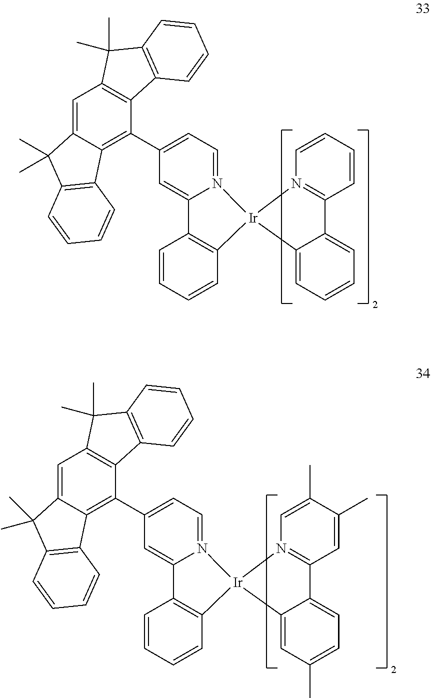

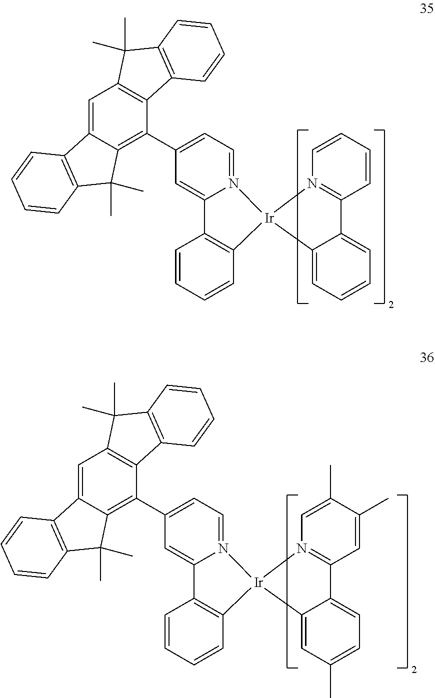

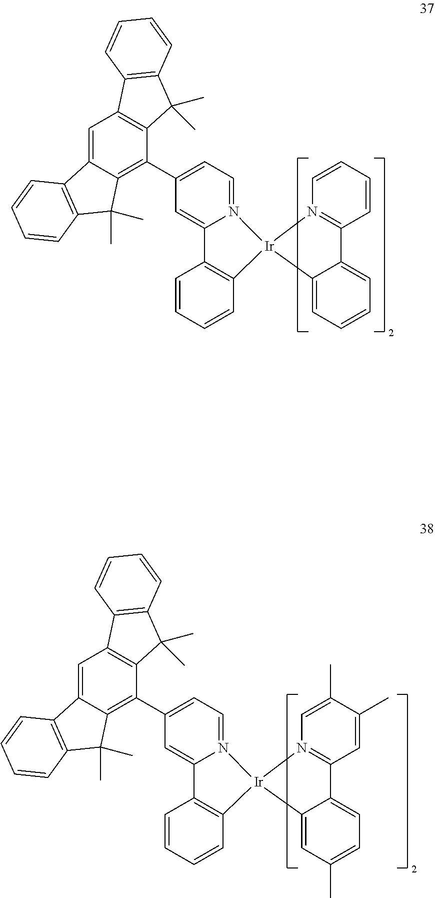

A thickness of each of the first electrode 110, the second electrode 120 and each of the layers included in the organic layer 130 according to the present disclosure is not particularly limited and may be adjusted as necessary. For example, a thickness of each of the first electrode 110 and the second electrode 120 may be in a range of 50 nm to 200 nm, a thickness of the hole injection layer 140 may be in a range of 5 nm to 10 nm, a thickness of the hole transfer layer 150 may be in a range of 5 nm to 130 nm, a thickness of the light-emitting layer 160 may be in a range of 5 nm to 50 nm, a thickness of the electron transfer layer 170 may be in a range of 5 nm to 50 nm, and a thickness of the electron injection layer 180 may be in a range of 5 nm to 50 nm.

The first electrode 110 may act as a positive electrode, and may be made of ITO, IZO, tin-oxide, or zinc-oxide as a conductive material having a relatively large work function value. However, the present disclosure is not limited thereto.

The second electrode 120 may act as a negative electrode, and may include aluminum (Al), magnesium (Mg), calcium (Ca), or silver (Ag) as a conductive material having a relatively small work function value, or an alloy or combination thereof. However, the present disclosure is not limited thereto.

The hole injection layer 140 may be positioned between the first electrode 110 and the hole transfer layer 150. The hole injection layer 140 may have a function of improving interface characteristics between the first electrode 110 and the hole transfer layer 150, and may be selected from a material having appropriate conductivity. The hole injection layer 140 may include a compound selected from a group consisting of a secondary amine-based compound, a tertiary amine-based compound, a radialene-based compound, an indacene-based compound, a metal cyanine-based compound, and combinations thereof. Specific examples thereof may include at least one selected from a group consisting of HATCN, MTDATA, TCTA, CuPc, TDAPB, PEDOT/PSS, N1,N1′-([1,1′-biphenyl]-4,4′-diyl)bis(N1,N4,N4-triphenylbenzene-1,4-diamine), and the like. In one embodiment, the hole injection layer 140 may include HATCN. However, the present disclosure is limited thereto.

The hole transfer layer 150 may be positioned adjacent to the light-emitting layer and between the first electrode 110 and the light-emitting layer 160. A material of the hole transfer layer 150 may include a compound selected from a group consisting of TAPC, TPD, NPB, CBP, N-(biphenyl-4-yl)-9,9-dimethyl-N-(4-(9-phenyl-9H to Carbazol-3-yl)phenyl)-9H-fluoren-2-amine, N-(biphenyl-4-yl)-N-(4-(9-phenyl-9H to Carbazol-3-yl)phenyl)biphenyl)-4-amine, and the like. In one embodiment, the material of the hole transfer layer 150 may include TAPC or NPB. However, the present disclosure is not limited thereto.

Further, the electron transfer layer 170 and the electron injection layer 180 may be sequentially stacked between the red light-emitting layer 160 and the second electrode 120. A material of the electron transfer layer 170 requires high electron mobility such that electrons may be stably supplied to the light-emitting layer under smooth electron transfer.

For example, the material of the electron transfer layer 170 may include a compound selected from a group consisting of Alq3 (tris(8-hydroxyquinolino)aluminum), Liq (8-hydroxyquinolinolatolithium), PBD (2-(4-biphenylyl)-5-(4-tert-butylphenyl)-1,3,4oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminium), SAlq, TPBi (2,2′,2-(1,3,5-benzinetriyl)-tris(1-phenyl-1-H-benzimidazole), oxadiazole, triazole, phenanthroline, benzoxazole, benzthiazole, ZADN (2-(4-(9,10-di(naphthalen-2-yl)anthracen-2-yl)phenyl)-1-phenyl-1H-benzo[d]imidazole), and the like. In one embodiment, the material of the electron transfer layer 170 may include ZADN. However, the present disclosure is not limited thereto.

The electron injection layer 180 may be disposed on the electron transfer layer 170 and serves to facilitate electron injection. A material of the electron injection layer may include an organic compound or an organometallic compound selected from a group consisting of Alq3 (tris(8-hydroxyquinolino)aluminum), PBD, TAZ, spiro-PBD, BAlq, SAlq, Bphen, and the like. However, the present disclosure is not limited thereto.

Alternatively, the electron injection layer 180 may include a mixture of the organic compound (or organometallic compound) and a metal material, or may include a metal material alone. For example, the electron injection layer 180 may include a mixture of Bphen and LiF. In this regard, the metal material may include, for example, one or more selected from a group consisting of Liq, LiF, NaF, KF, RbF, CsF, FrF, BeF₂, MgF₂, CaF₂, SrF₂, BaF₂, RaF₂, and the like. However, the present disclosure is not limited thereto. Further, a material of the electron injection layer 180 may include a mixture of the metal material and a metal element having a low work function, such as ytterbium (Yb), calcium (Ca), strontium (Sr), barium (Ba), lanthanum (La), etc. For example, a mixture of LiF and ytterbium (Yb) may be used as a material of the electron injection layer 180.

In addition, although not shown in FIG. 1, a hole transfer auxiliary layer may be further added between the hole transfer layer 150 and the light-emitting layer 160. The hole transfer auxiliary layer includes a compound having good hole transfer properties, and reduces a difference between the HOMO energy levels of the hole transfer layer 150 and the light-emitting layer 160 to control the hole injection characteristics to reduce the accumulation of holes at the interface between the hole transfer auxiliary layer and the light-emitting layer 160, such that the deterioration of the diode is reduced, and the diode is stabilized to improve the efficiency and lifespan thereof.

The applicants of the present disclosure have carried out intensive research, and thus have experimentally identified that when the light-emitting layer 160 includes the two types of hosts, that is, the first host 160′ and the second host 160″ in accordance with the present disclosure, the light-emitting efficiency of the phosphorescent light-emitting layer can be further improved while further lowering the operation voltage of the phosphorescent light-emitting layer. Thus, the present disclosure has been completed. Hereinafter, the two types of hosts according to the present disclosure will be described in detail.

As shown in FIG. 1 as one embodiment of the present disclosure, the light-emitting layer 160 is embodied as a red light-emitting layer including the two types of hosts, that is, the first host 160′ and the second host 160″. The two types of hosts are the hole type host (red hole type host) and the electron type host (red electron type host), respectively and are referred to as the first host 160′ and the second host 160″, respectively.

In order that the first host 160′ and the second host 160″ according to the present disclosure achieve the above effect, that is, act as the hole type host and the electron type host, respectively, the first host 160′ and the second host 160″ according to the present disclosure should satisfy a specific energy level relationship. A combination of the host materials satisfying the specific energy level relationship may be contained in the light-emitting layer 160.

Specifically, the first host 160′ as the hole type host in the light-emitting layer may mainly play a role of receiving the holes transferred/injected from the hole transfer layer and supplying the same to the light-emitting layer, while the second host 160″ as the electron type host may mainly play a role of receiving electrons transferred/injected from the electron transfer layer and supplying the same to the light-emitting layer. The specific energy level relationship of the two types of hosts may be specified such that the main role of each of the first host 160′ and the second host 160″ may be efficiently performed to achieve the purpose of the present disclosure.

From this point of view, the absolute value of the HOMO energy level of the first host 160′ of the present disclosure should be smaller than or equal to the absolute value of the HOMO energy level of the second host 160″. This may be expressed as a following Relationship (1):

$$\vert {HOMO}_{( HOST - 1 )} \vert \leq \vert {HOMO}_{( HOST - 2 )} \vert \qquad Relationship ( 1 )$$

In the Relationship (1), |HOMO_{(HOST-1)}| and |HOMO_{(HOST-2)}| denote the absolute values of the HOMO energy levels of the first host and the second host, respectively. According to an embodiment of the present disclosure, the |HOMO_{(HOST-1)}| may be in a range of 5.0 to 6.0 (eV), and the |HOMO_{(HOST-2)}| may be in a range of 5.2 to 6.2 (eV).

A mixing ratio of the two types of hosts is not particularly limited. The first host has hole transfer ability, and the second host has electron transfer ability. Thus, the mixture of the first host and the second host may allow the lifespan of the light-emitting diode to be increased. The operation voltage and the light-emitting efficiency thereof may be appropriately adjusted according to the mixing ratio of the first host and the second host. Therefore, the mixing ratio of the first host and the second host is not particularly limited. The mixing ratio (by weight) of the first host and the second host may be in a range of, for example, 1:9 to 9:1, for example, 2:8, for example 3:7, for example 4:6, for example, 5:5, for example, 6:4, for example, 7:3, for example, 8:2.

According to one embodiment of the present disclosure, a material is selected having an ability of transferring and injecting the holes as the material of the first host 160′.

For example, the first host 160′ may include a tertiary amine-based compound and a compound including a carbazole group. However, the present disclosure is not limited thereto. Any host material may be employed as the first host as long as it has the hole transfer/injection ability.

More specifically, an example of the ‘tertiary amine-based compound’ as a material of the first host 160′ may include a tertiary amine-based compound including a spiro structure, NPB and its derivatives, TAPC, TPD, or the like. However, the present disclosure is not limited thereto. Further, an example of the ‘compound including a carbazole group’ as the material of the first host 160′ may include mCP, TCB, CBP, TCTA, or the like. However, the present disclosure is not limited thereto.

A structure of the above-described example compound of the first host is shown below, and the HOMO energy level of a representative example of the material of the first host is indicated in a following Table 1:

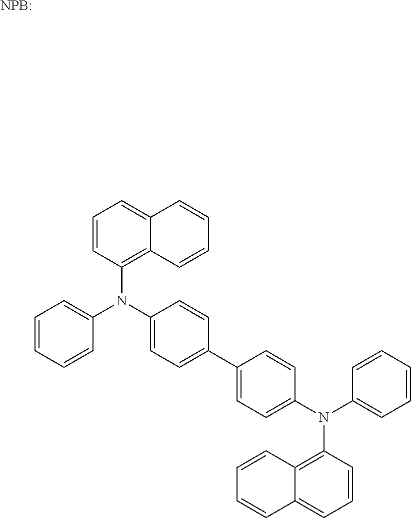

### Derivative of NPB:

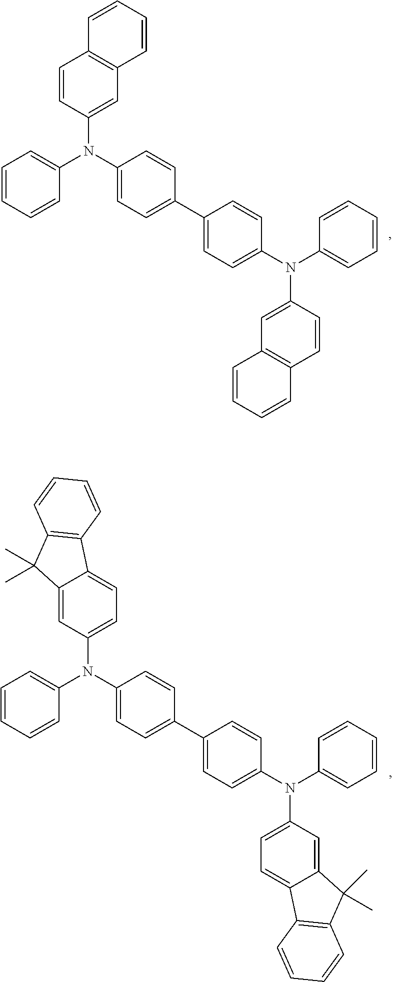 [SMILES: c1ccc(N(c2ccc(-c3ccc(N(c4ccccc4)c4ccc5ccccc5c4)cc3)cc2)c2ccc3ccccc3c2)cc1 ; CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21]

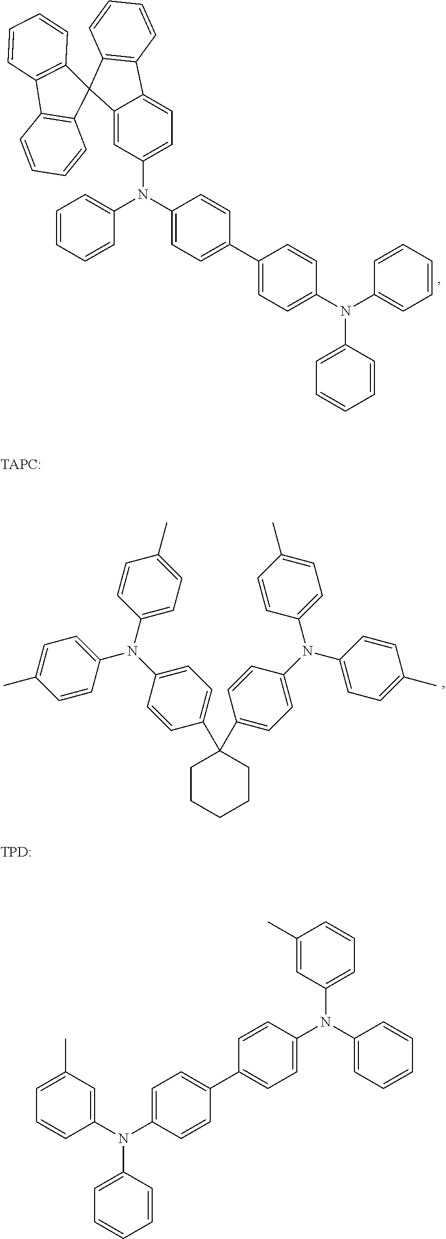

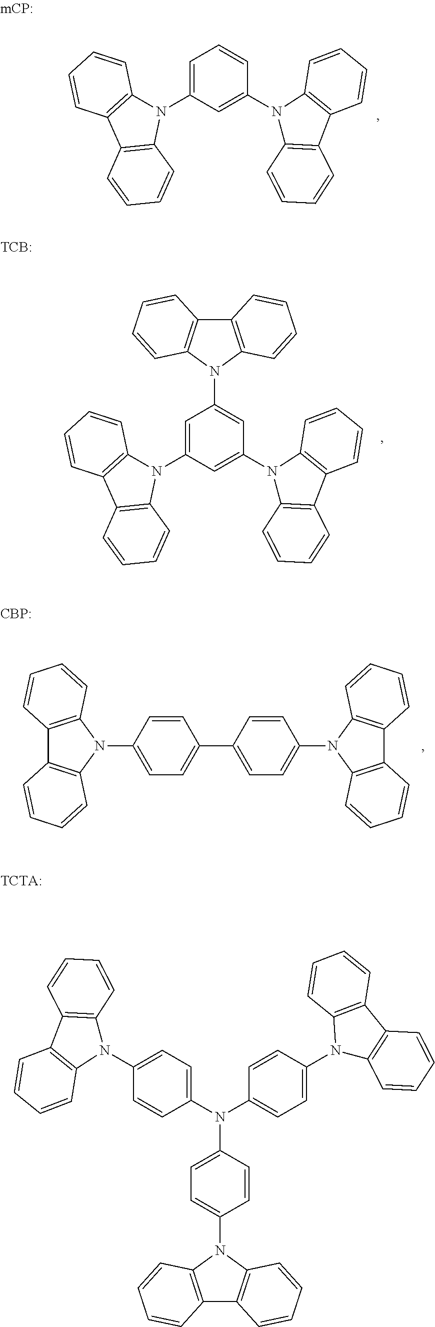

### Tertiary Amine-Based Compound Including Spiro Structure:

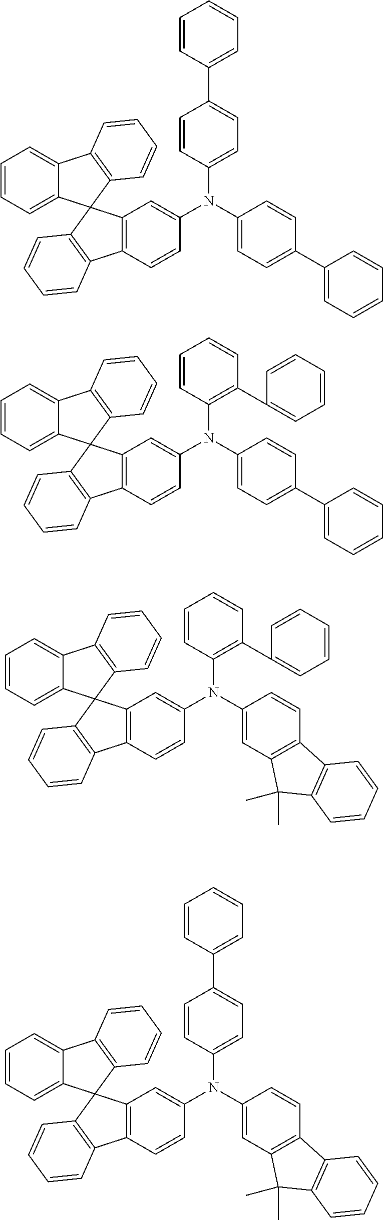 [SMILES: c1ccc(-c2ccc(N(c3ccc(-c4ccccc4)cc3)c3ccc4c(c3)C3(c5ccccc5-c5ccccc53)c3ccccc3-4)cc2)cc1 ; c1ccc(-c2ccc(N(c3ccc4c(c3)C3(c5ccccc5-c5ccccc53)c3ccccc3-4)c3ccccc3-c3ccccc3)cc2)cc1 ; CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21]

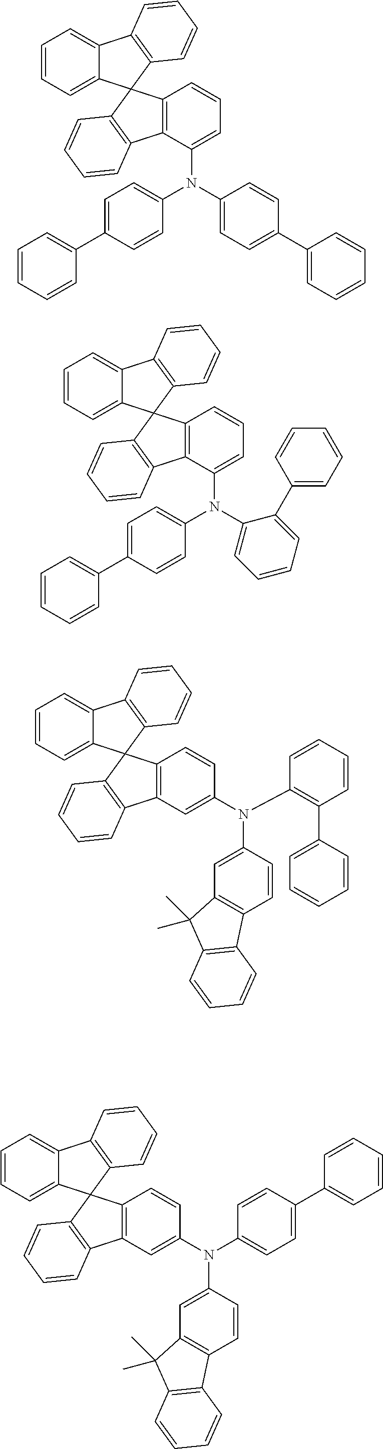 [SMILES: c1ccc(-c2ccc(N(c3ccc(-c4ccccc4)cc3)c3cccc4c3-c3ccccc3C43c4ccccc4-c4ccccc43)cc2)cc1 ; c1ccc(-c2ccc(N(c3ccccc3-c3ccccc3)c3cccc4c3-c3ccccc3C43c4ccccc4-c4ccccc43)cc2)cc1 ; CC1(C)c2ccccc2-c2ccc(N(c3ccc4c(c3)-c3ccccc3C43c4ccccc4-c4ccccc43)c3ccccc3-c3ccccc3)cc21 ; CC1(C)c2ccccc2-c2ccc(N(c3ccc(-c4ccccc4)cc3)c3ccc4c(c3)-c3ccccc3C43c4ccccc4-c4ccccc43)cc21]

TABLE 1

| First host | HOMO energy level (eV) |
|---|---|
| TPD | −5.50 |
| TAPC | −5.50 |
| NPB | −5.50 |
| TCTA | −5.83 |
| mCP | −5.90 |
| CBP | −6.00 |

According to one embodiment of the present disclosure, a material is selected having an ability of transferring and injecting electrons as the material of the second host. For example, the second host may include a compound including a pyridine group (e.g., TmPyPB, etc.), a compound including a pyrimidine group (e.g., DMAC-BPP, B3PYMPM, etc.), a compound including a triazine group (e.g., PTC, T2T, 3N-T2T, PXZ-TRZ, DPTPCz, etc.), a compound including a quinazoline group or the like. However, the present disclosure is not limited thereto. Any host material having electron transfer/injection ability may be used as the material of the second host according to the present disclosure.

More specifically, a structure of the compound as a material that may be used as the second host is shown below, and the HOMO energy level of a representative example of the material of the second host is indicated in a following Table 2.

### Compound Including Pyridine Group:

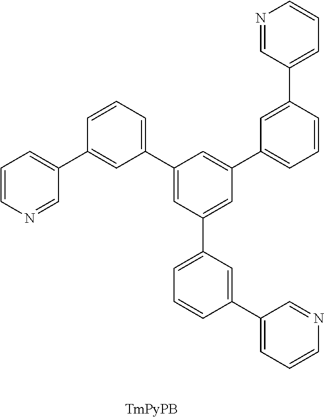 [SMILES: c1cncc(-c2cccc(-c3cc(-c4cccc(-c5cccnc5)c4)cc(-c4cccc(-c5cccnc5)c4)c3)c2)c1]

### Compound Including Pyrimidine Group:

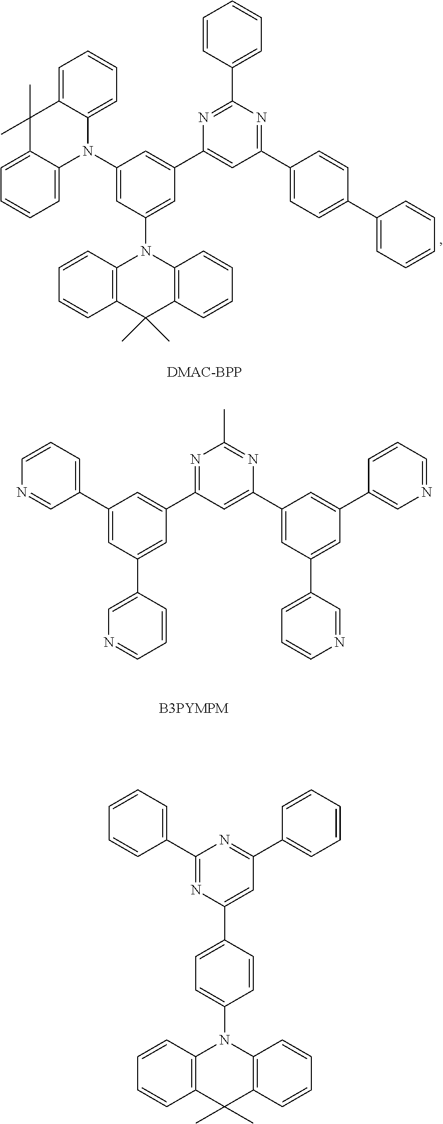 [SMILES: CC1(C)c2ccccc2N(c2cc(-c3cc(-c4ccc(-c5ccccc5)cc4)nc(-c4ccccc4)n3)cc(N3c4ccccc4C(C)(C)c4ccccc43)c2)c2ccccc21 ; Cc1nc(-c2cc(-c3cccnc3)cc(-c3cccnc3)c2)cc(-c2cc(-c3cccnc3)cc(-c3cccnc3)c2)n1 ; CC1(C)c2ccccc2N(c2ccc(-c3cc(-c4ccccc4)nc(-c4ccccc4)n3)cc2)c2ccccc21]

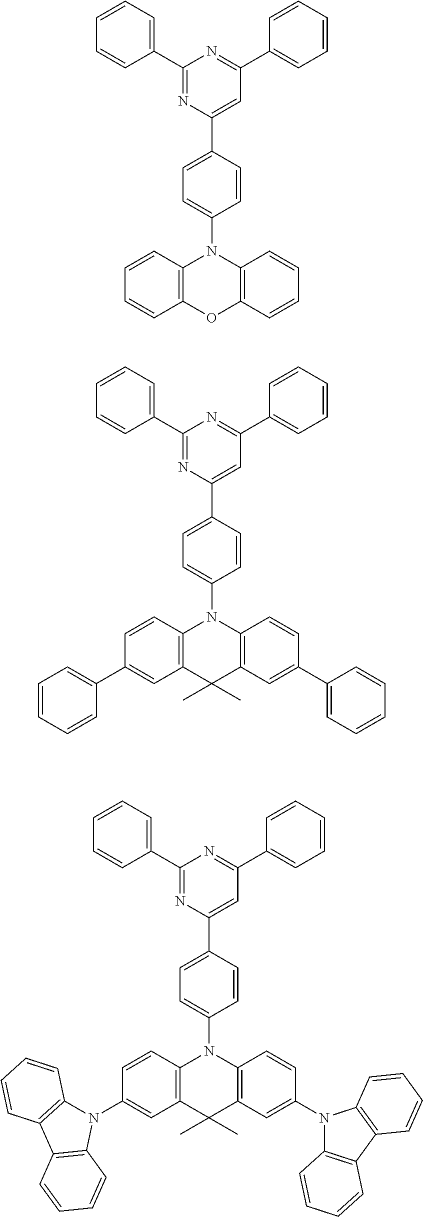 [SMILES: c1ccc(-c2cc(-c3ccc(N4c5ccccc5Oc5ccccc54)cc3)nc(-c3ccccc3)n2)cc1 ; CC1(C)c2cc(-c3ccccc3)ccc2N(c2ccc(-c3cc(-c4ccccc4)nc(-c4ccccc4)n3)cc2)c2ccc(-c3ccccc3)cc21 ; CC1(C)c2cc(-n3c4ccccc4c4ccccc43)ccc2N(c2ccc(-c3cc(-c4ccccc4)nc(-c4ccccc4)n3)cc2)c2ccc(-n3c4ccccc4c4ccccc43)cc21]

### Compound Including Triazine Group:

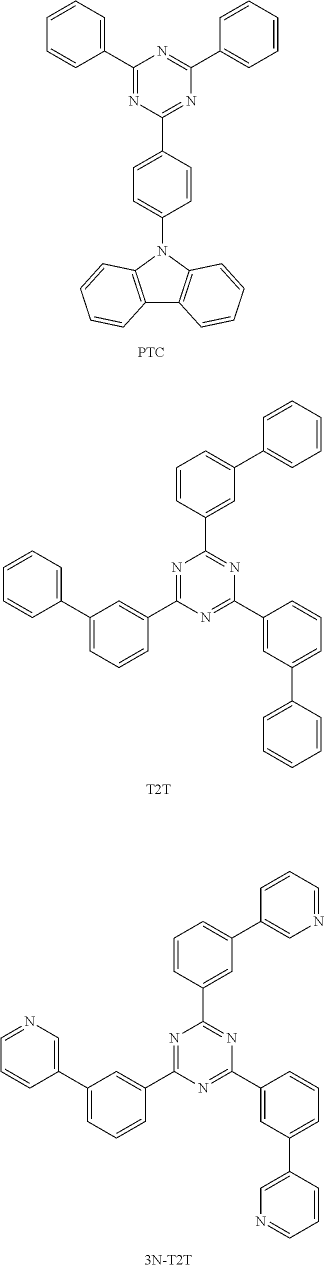

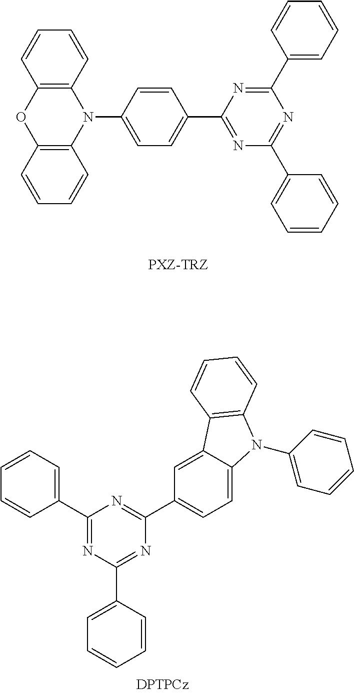 [SMILES: c1ccc(-c2nc(-c3ccccc3)nc(-c3ccc(N4c5ccccc5Oc5ccccc54)cc3)n2)cc1 ; c1ccc(-c2nc(-c3ccccc3)nc(-c3ccc4c(c3)c3ccccc3n4-c3ccccc3)n2)cc1]

### Compound Including Quinazoline Group:

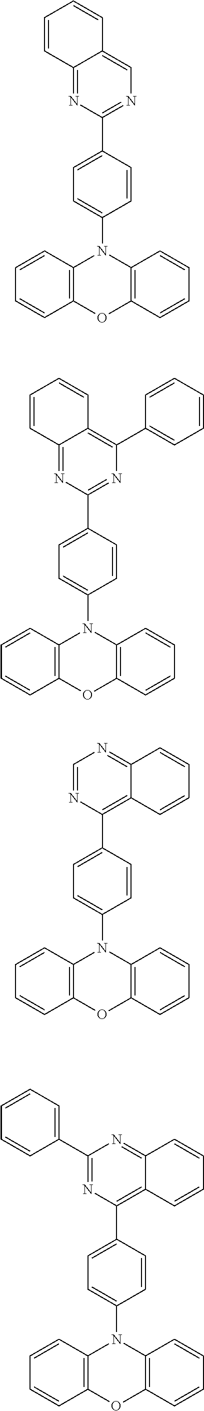 [SMILES: c1ccc2c(c1)Oc1ccccc1N2c1ccc(-c2ncc3ccccc3n2)cc1 ; c1ccc(-c2nc(-c3ccc(N4c5ccccc5Oc5ccccc54)cc3)nc3ccccc23)cc1 ; c1ccc2c(c1)Oc1ccccc1N2c1ccc(-c2ncnc3ccccc23)cc1 ; c1ccc(-c2nc(-c3ccc(N4c5ccccc5Oc5ccccc54)cc3)c3ccccc3n2)cc1]

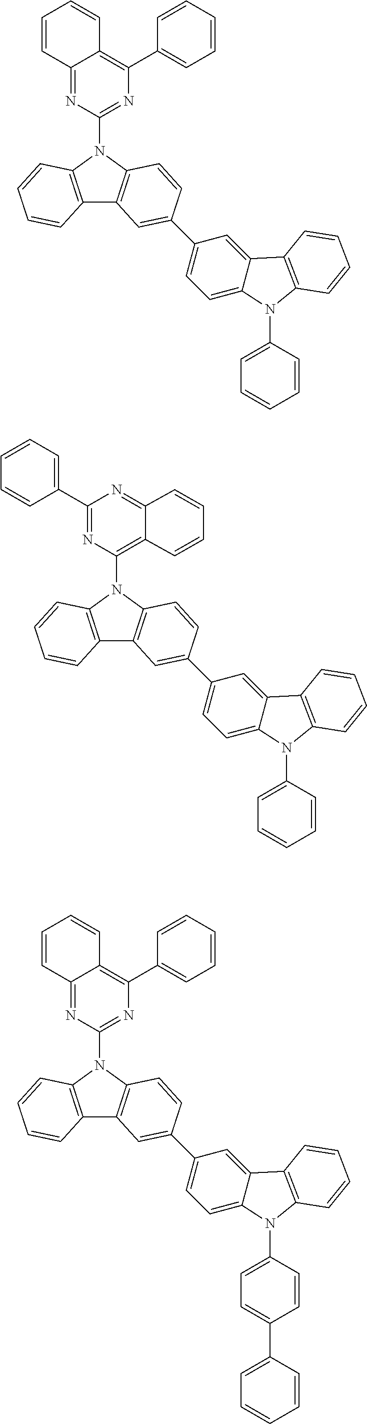 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-n3c4ccccc4c4cc(-c5ccc6c(c5)c5ccccc5n6-c5ccccc5)ccc43)c3ccccc3n2)cc1 ; c1ccc(-c2ccc(-n3c4ccccc4c4cc(-c5ccc6c(c5)c5ccccc5n6-c5nc(-c6ccccc6)c6ccccc6n5)ccc43)cc2)cc1]

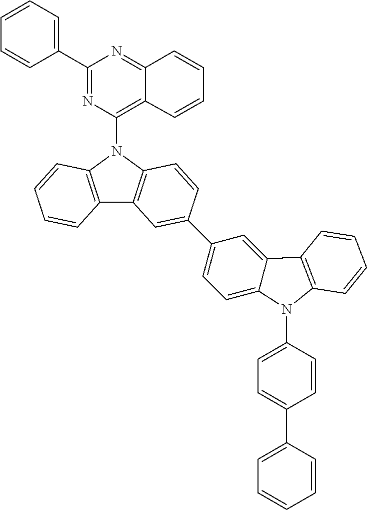 [SMILES: c1ccc(-c2ccc(-n3c4ccccc4c4cc(-c5ccc6c(c5)c5ccccc5n6-c5nc(-c6ccccc6)nc6ccccc56)ccc43)cc2)cc1]

TABLE 2

| Second host | HOMO energy level (eV) |
|---|---|
| DMAC-BPP | −5.38 |
| PXZ-TRZ | −5.50 |
| DPTPCz | −5.65 |
| PTC | −5.90 |
| TmPyPB | −6.75 |

The light-emitting layer 160 of the present disclosure may be a red light-emitting layer. In this case, the red light-emitting layer 160 according to the present disclosure may be formed by doping the dopant 160′″ to the combination of the hosts 160′ and 160″. For example, the dopant 160′″ may include a metal complex (organometallic compound) of iridium (Ir) or platinum (Pt) having a larger atomic number. The iridium (Ir) metal complex is preferable. More specifically, the dopant 160′″ may include a dopant material selected from Ir(piq)₃, Ir(piq)₂(acac), Ir(2-phq)₃, Ir(ppy)₃, Ir(ppy)₂(bpmp), Ir(ppz)₃, Ir(piq)₃, Ir(ppy)₂(bpmp), and the like. However, the present disclosure is not limited thereto.

In this way, the light-emitting layer 160 of the present disclosure may be formed by doping the host 160′ and 160″ with the dopant 160′″ in order to improve luminous efficiency of the diode.

In one embodiment, a doping concentration of the dopant 160′″ may be in a range of 1% to 30% by weight, based on a total weight of the two hosts 160′ and 160″. For example, the doping concentration of the red dopant 160′″ may be in a range of 2% to 20% by weight, such as 3% to 15% by weight, such as 5% to 10% by weight, such as 3% to 8% by weight, such as 2% to 6% by weight, such as 2% to 5% by weight, based on the total weight of the two hosts 160′ and 160″. The present disclosure is not limited thereto, and the doping concentration of the dopant 160′″ may be adjusted based on a type of a material of the organic layer as used.

The organic light-emitting diode according to the present disclosure may be embodied as a white light-emitting diode having a tandem structure. The tandem organic light-emitting diode according to an illustrative embodiment of the present disclosure may be formed in a structure in which adjacent ones of two or more light-emitting stacks are connected to each other via a charge generation layer (CGL). The organic light-emitting diode may include at least two light-emitting stacks disposed on a substrate, wherein each of the at least two light-emitting stacks includes first and second electrodes facing each other, and the light-emitting layer disposed between the first and second electrodes to emit light in a specific wavelength band. The plurality of light-emitting stacks may emit light of the same color or different colors. In addition, one or more light-emitting layers may be included in one light-emitting stack, and the plurality of light-emitting layers may emit light of the same color or different colors.

As shown in FIG. 2, an organic light-emitting diode 100 according to the present disclosure include a first electrode 110 and a second electrode 120 facing each other, and an organic layer 230 positioned between the first electrode 110 and the second electrode 120. The organic layer 230 may be positioned between the first electrode 110 and the second electrode 120 and may include a first light-emitting stack ST1 including a first light-emitting layer 261, a second light-emitting stack ST2 positioned between the first light-emitting stack ST1 and the second electrode 120 and including a second light-emitting layer 262, and the charge generation layer CGL positioned between the first and second light-emitting stacks ST1 and ST2. The charge generation layer CGL may include an N-type charge generation layer 291 and a P-type charge generation layer 292. At least one of the first light-emitting layer 261 and the second light-emitting layer 262 may be a red light-emitting layer according to the present disclosure.

As shown in FIG. 2, the hole scavenger layer (HSL) may be disposed between the second light-emitting layer 262 and the second electron transfer layer 272. Although not shown in FIG. 2, a further hole scavenger layer may also be introduced between the first light-emitting layer 261 and the first electron transfer layer 271. The hole scavenger layer (HSL) may include the complex compound represented by the Chemical Formula 1 of the present disclosure.

As shown in FIG. 2, the second light-emitting layer 262 of the second light-emitting stack ST2 may be a red light-emitting layer, and may include the two types of hosts, that is, a first host 262′ and a second host 262″, and a dopant 262′ doped thereto. In this case, the dopant 262′″ may be a red dopant.

Although not explicitly shown in FIG. 2, each of the first and second light-emitting stacks ST1 and ST2 may further include, in addition to each of the first light-emitting layer 261 and the second light-emitting layer 262, an additional light-emitting layer.

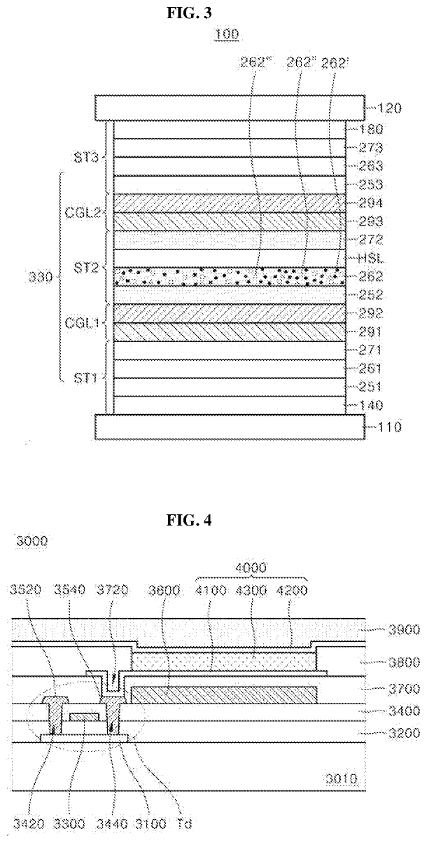

As shown in FIG. 3, the organic light-emitting diode 100 according to the present disclosure include the first electrode 110 and the second electrode 120 facing each other, and an organic layer 330 positioned between the first electrode 110 and the second electrode 120. The organic layer 330 may be positioned between the first electrode 110 and the second electrode 120 and may include the first light-emitting stack ST1 including the first light-emitting layer 261, the second light-emitting stack ST2 including the second light-emitting layer 262, a third light-emitting stack ST3 including a third light-emitting layer 263, a first charge generation layer CGL1 positioned between the first and second light-emitting stacks ST1 and ST2, and a second charge generation layer CGL2 positioned between the second and third light-emitting stacks ST2 and ST3. The first charge generation layer CGL1 may include a N-type charge generation layers 291 and a P-type charge generation layer 292. The second charge generation layer CGL2 may include a N-type charge generation layers 293 and a P-type charge generation layer 294.

As shown in FIG. 3, the hole scavenger layer (HSL) may be disposed between the second light-emitting layer 262 and the second electron transfer layer 272, Although not shown in FIG. 3, a further hole scavenger layer may be further formed between the first light-emitting layer 261 and the first electron transfer layer 271 and/or between the third light-emitting layer 263 and the third electron transfer layer 273. The hole scavenger layer (HSL) may include the complex compound represented by the Chemical Formula 1 of the present disclosure.

As shown in FIG. 3, the second light-emitting layer 262 of the second light-emitting stack ST2 may be a red light-emitting layer. In this case, the second light-emitting layer 262 may include two kinds of hosts, that is, the first host 262′ and the second host 262″, and the dopant 262′″. In this case, the dopant 262′″ may be a red dopant.

Although not explicitly shown in FIG. 3, each of the first to third light-emitting stacks ST1 to ST3 may further include, in addition to each of the first to third light-emitting layers 261 to 263, an additional light-emitting layer.

Furthermore, an organic light-emitting diode according to an embodiment of the present disclosure may include a tandem structure in which four or more light-emitting stacks and three or more charge generating layers are disposed between the first electrode and the second electrode.

The organic light-emitting diode according to the present disclosure may be used as a light-emitting element of each of an organic light-emitting display device and a lighting device. In one implementation, FIG. 4 is a cross-sectional view schematically illustrating an organic light-emitting display device including the organic light-emitting diode according to some embodiments of the present disclosure as a light-emitting element thereof.

As shown in FIG. 4, an organic light-emitting display device 3000 includes a substrate 3010, an organic light-emitting diode 4000, and an encapsulation film 3900 covering the organic light-emitting diode 4000. A driving thin-film transistor Td as a driving element, and the organic light-emitting diode 4000 connected to the driving thin-film transistor Td are positioned on the substrate 3010.

Although not shown explicitly in FIG. 4, a gate line and a data line that intersect each other to define a pixel area, a power line extending parallel to and spaced from one of the gate line and the data line, a switching thin film transistor connected to the gate line and the data line, and a storage capacitor connected to one electrode of the thin film transistor and the power line are further formed on the substrate 3010.

The driving thin-film transistor Td is connected to the switching thin film transistor, and includes a semiconductor layer 3100, a gate electrode 3300, a source electrode 3520, and a drain electrode 3540.

The semiconductor layer 3100 may be formed on the substrate 3010 and may be made of an oxide semiconductor material or polycrystalline silicon. When the semiconductor layer 3100 is made of an oxide semiconductor material, a light-shielding pattern (not shown) may be formed under the semiconductor layer 3100. The light-shielding pattern prevents or at least reduces light from being incident into the semiconductor layer 3100 to prevent the semiconductor layer 3100 from being deteriorated due to the light. Alternatively, the semiconductor layer 3100 may be made of polycrystalline silicon. In this case, both edges of the semiconductor layer 3100 may be doped with impurities.

The gate insulating layer 3200 made of an insulating material is formed over an entirety of a surface of the substrate 3010 and on the semiconductor layer 3100. The gate insulating layer 3200 may be made of an inorganic insulating material such as silicon oxide or silicon nitride.

The gate electrode 3300 made of a conductive material such as a metal is formed on the gate insulating layer 3200 and corresponds to a center of the semiconductor layer 3100. The gate electrode 3300 is connected to the switching thin film transistor.

The interlayer insulating layer 3400 made of an insulating material is formed over the entirety of the surface of the substrate 3010 and on the gate electrode 3300. The interlayer insulating layer 3400 may be made of an inorganic insulating material such as silicon oxide or silicon nitride, or an organic insulating material such as benzocyclobutene or photo-acryl.

The interlayer insulating layer 3400 has first and second semiconductor layer contact holes 3420 and 3440 defined therein respectively exposing both opposing sides of the semiconductor layer 3100. The first and second semiconductor layer contact holes 3420 and 3440 are respectively positioned on both opposing sides of the gate electrode 3300 and are spaced apart from the gate electrode 3300.

The source electrode 3520 and the drain electrode 3540 made of a conductive material such as metal are formed on the interlayer insulating layer 3400. The source electrode 3520 and the drain electrode 3540 are positioned around the gate electrode 3300, and are spaced apart from each other, and respectively contact both opposing sides of the semiconductor layer 3100 via the first and second semiconductor layer contact holes 3420 and 3440, respectively. The source electrode 3520 is connected to a power line (not shown).

The semiconductor layer 3100, the gate electrode 3300, the source electrode 3520, and the drain electrode 3540 constitute the driving thin-film transistor Td. The driving thin-film transistor Td has a coplanar structure in which the gate electrode 3300, the source electrode 3520, and the drain electrode 3540 are positioned on top of the semiconductor layer 3100.

Alternatively, the driving thin-film transistor Td may have an inverted staggered structure in which the gate electrode is disposed under the semiconductor layer while the source electrode and the drain electrode are disposed above the semiconductor layer. In this case, the semiconductor layer may be made of amorphous silicon. In one example, the switching thin-film transistor (not shown) may have substantially the same structure as that of the driving thin-film transistor (Td).

In one example, the organic light-emitting display device 3000 may include a color filter 3600 absorbing the light generated from the electroluminescent element (light-emitting diode) 4000. For example, the color filter 3600 may absorb red (R), green (G), blue (B), and white (W) light. In this case, red, green, and blue color filter patterns that absorb light may be formed separately in different pixel areas. Each of these color filter patterns may be disposed to overlap each organic layer 4300 of the organic light-emitting diode 4000 to emit light of a wavelength band corresponding to each color filter. Adopting the color filter 3600 may allow the organic light-emitting display device 3000 to realize full to Color.

For example, when the organic light-emitting display device 3000 is of a bottom emission type, the color filter 3600 absorbing light may be positioned on a portion of the interlayer insulating layer 3400 corresponding to the organic light-emitting diode 4000. In an optional embodiment, when the organic light-emitting display device 3000 is of a top emission type, the color filter may be positioned on top of the organic light-emitting diode 4000, that is, on top of a second electrode 4200. For example, the color filter 3600 may be formed to have a thickness of 2 μm to 5 μm.

In one example, a planarization layer 3700 having a drain contact hole 3720 defined therein exposing the drain electrode 3540 of the driving thin-film transistor Td is formed to cover the driving thin-film transistor Td.

On the planarization layer 3700, each first electrode 4100 connected to the drain electrode 3540 of the driving thin-film transistor Td via the drain contact hole 3720 is formed individually in each pixel area.

The first electrode 4100 may act as a positive electrode (anode), and may be made of a conductive material having a relatively large work function value. For example, the first electrode 4100 may be made of a transparent conductive material such as ITO, IZO or ZnO.

In one example, when the organic light-emitting display device 3000 is of a top-emission type, a reflective electrode or a reflective layer may be further formed under the first electrode 4100. For example, the reflective electrode or the reflective layer may be made of one of aluminum (Al), magnesium (Mg), silver (Ag), nickel (Ni), and an aluminum-palladium to Copper (APC) alloy.

A bank layer 3800 covering an edge of the first electrode 4100 is formed on the planarization layer 3700. The bank layer 3800 exposes a center of the first electrode 4100 corresponding to the pixel area.

An organic layer 4300 is formed on the first electrode 4100. If necessary, the organic light-emitting diode 4000 may have a tandem structure. Regarding the tandem structure, reference may be made to FIG. 2 to FIG. 3 which show some embodiments of the present disclosure, and the above descriptions thereof.

The second electrode 4200 is formed on the substrate 3010 on which the organic layer 4300 has been formed. The second electrode 4200 is disposed over the entirety of the surface of the display area and is made of a conductive material having a relatively small work function value and may be used as a negative electrode (a cathode). For example, the second electrode 4200 may be made of one of aluminum (Al), magnesium (Mg), and an aluminum-magnesium alloy (Al—Mg).

The first electrode 4100, the organic layer 4300, and the second electrode 4200 constitute the organic light-emitting diode 4000.

An encapsulation film 3900 is formed on the second electrode 4200 to prevent external moisture from penetrating into the organic light-emitting diode 4000. Although not shown explicitly in FIG. 4, the encapsulation film 3900 may have a triple-layer structure in which a first inorganic layer, an organic layer, and an inorganic layer are sequentially stacked. However, the present disclosure is not limited thereto.

Hereinafter, Synthesis Example and Present Example of the present disclosure will be described. However, following Present Example is only one example of the present disclosure. The present disclosure is not limited thereto.

### Synthesis Example

### Preparation of Ligand A-3

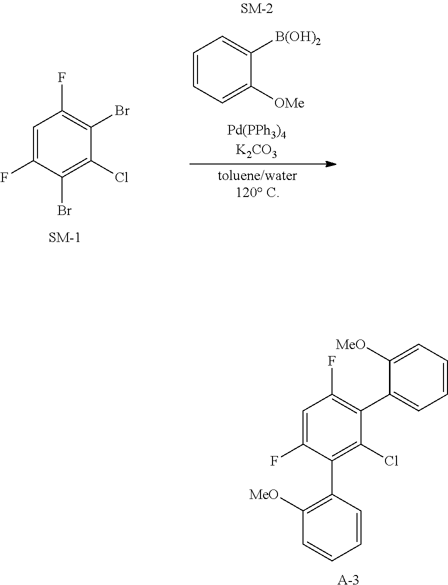

A compound SM-1 (6.12 g, 20 mmol), a compound SM-2 (3.04 g, 20 mmol), Pd(PPh₃)₄ (1.2 g, 1 mmol), and K₂CO₃ (8.3 g, 60 mmol) were dissolved in a mixture of 200 ml of toluene and 50 ml of water in a 500 ml round bottom flask under a nitrogen atmosphere, and a mixed solution was stirred under reflux for 12 hours. An organic layer was extracted therefrom with chloroform and washed with water. Moisture was removed therefrom with anhydrous magnesium sulfate, and a resulting product was filtered through a filter, and the organic solvent was distilled off under reduced pressure, followed by column purification to obtain the Compound A-3 (6.35 g, a yield: 88%).

### Preparation of Ligand A-2

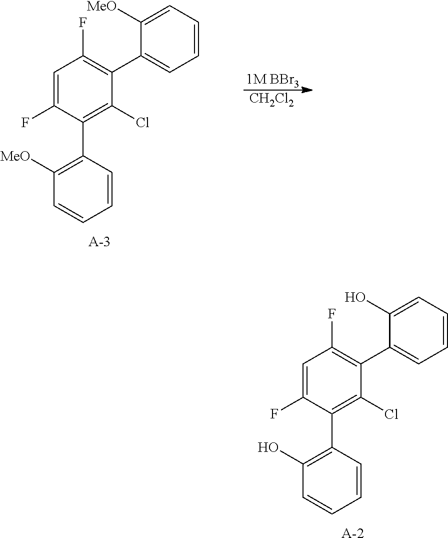

The Compound A-3 (7.22 g, 20 mmol), 1M BBr₃ (46 ml, 46 mmol), and CH₂Cl₂ (300 ml) were added to a 500 ml round bottom flask under a nitrogen atmosphere, and a mixture was stirred at 0° C. for 8 hours, and reaction occurred overnight at room temperature. After completion of the reaction, a reaction product was neutralized with a saturated aqueous NaHCO₃ solution. A sample was transferred to a separatory funnel, and was subjected to extraction with CH₂Cl₂, and was purified using column chromatography to prepare the Compound A-2 (5.93 g, a yield: 89%).

### Preparation of Ligand A-1

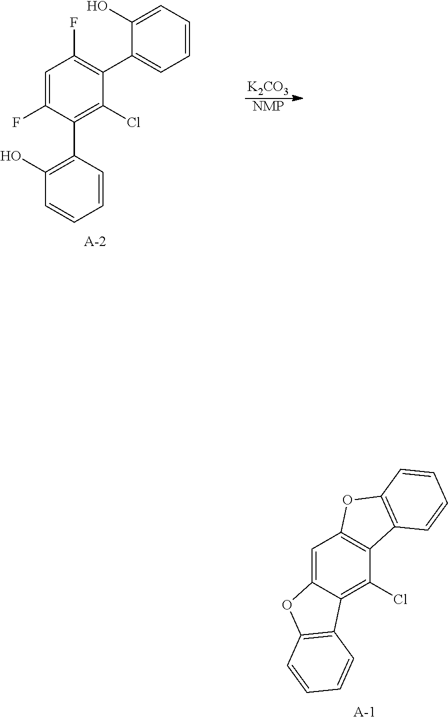

The Compound A-2 (6.66 g, 20 mmol), K₂CO₃ (6.07 g, 44 mmol), and NMP (200 ml) were input into a 500 ml round bottom flask under a nitrogen atmosphere, and a mixture was stirred at 150 degree C. for 8 hours, and then cooled to room temperature. A sample was transferred to a separatory funnel, and water (200 ml) was added thereto, and was subjected to extraction with AcOEt. The sample was purified using column chromatography. Thus, the Compound A-1 (5.16 g, a yield: 88%) was prepared.

### Preparation of ligand A

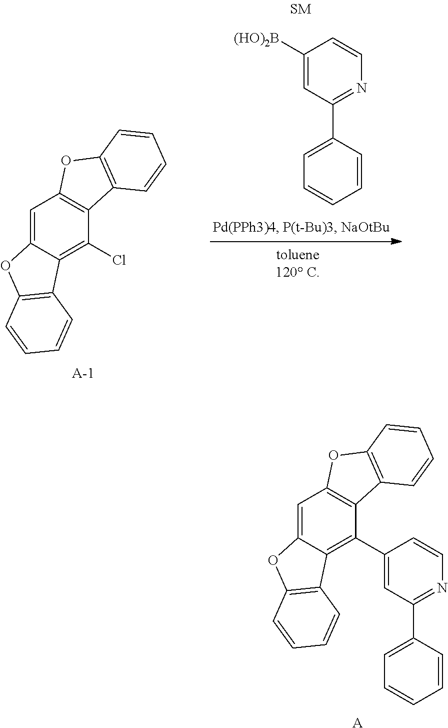

The Compound A-1 (5.86 g, 20 mmol), a compound SM (3.98 g, 20 mmol), Pd(PPh₃)₄ (2.3 g, 2 mmol), P(t-Bu)₃ (0.81 g, 4 mmol) and NaOtBu (7.7 g, 80 mmol) were dissolved in 200 ml of toluene in a 500 ml round bottom flask under a nitrogen atmosphere, and a mixed solution was stirred under reflux for 12 hours. An organic layer was extracted therefrom with chloroform and washed with water. Moisture was removed therefrom with anhydrous magnesium sulfate, and a resulting product was filtered through a filter, and the organic solvent was distilled off under reduced pressure, followed by column purification to obtain the Compound A (7.33 g, a yield: 89%).

### Preparation of Compound B

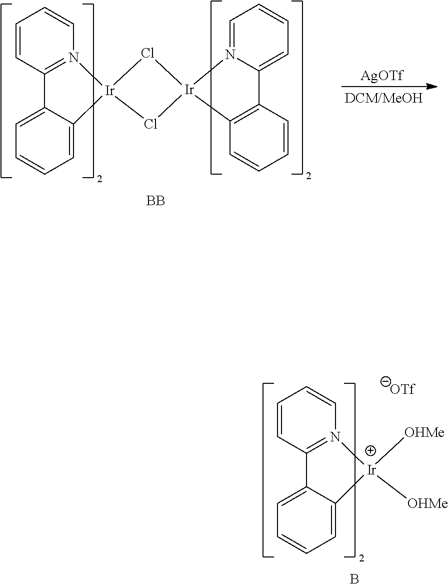

BB (5.16 g, 4.8 mmol), silver trifluoromethanesulfonate (AgOTf, 3.6 g, 14.3 mmol), and dichloromethane were placed into a 1000 ml round-bottom flask and a mixture was stirred at room temperature for 16 hours for reaction. After the reaction is completed, a solid is removed therefrom via filtration using celite. The solvent was distilled off under reduced pressure. Thus, the resulting solid Compound B (6.03 g, a yield: 88%) was obtained.

### Preparation of Iridium Compound 1

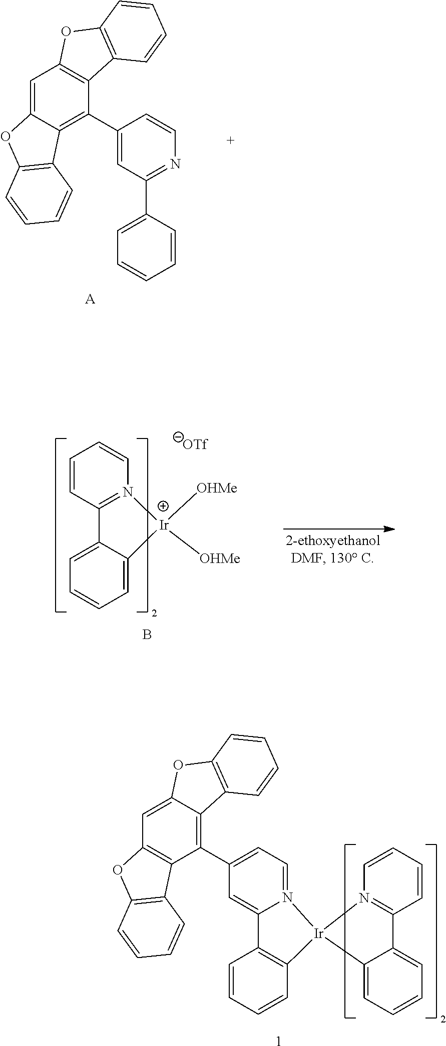

The iridium precursor B (2.15 g. 3.5 mmol) and the ligand A (1.44 g, 3 mmol) were dissolved in a mixed solvent (2-ethoxyethanol: DMF=40 ml: 40 ml) in a 100 ml round bottom flask under a nitrogen atmosphere and a mixed solution was stirred at 130 degrees C. for 48 hours for reaction. After the reaction was completed, an organic layer was extracted therefrom with dichloromethane and distilled water, and the solvent was removed therefrom via distillation under reduced pressure. A crude product was subjected to column chromatography with toluene: hexane to obtain the iridium compound 1 (2.57 g, a yield: 94%).

### Preparation of ligand C

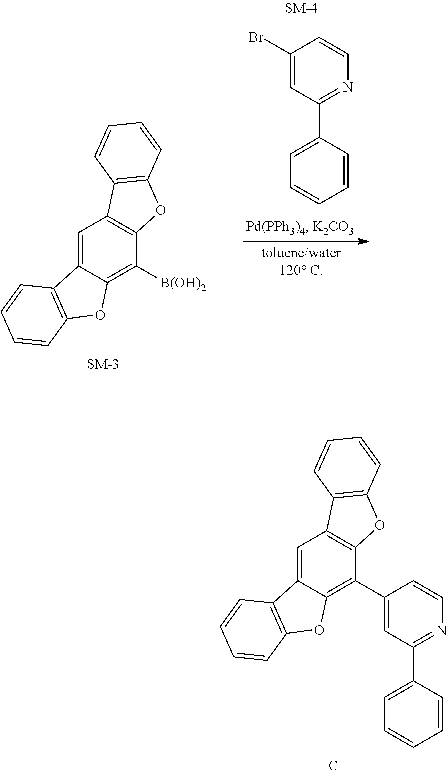

A compound SM-3 (6.04 g, 20 mmol), a compound SM-4 (4.68 g, 20 mmol), Pd(PPh₃)₄ (1.2 g, 1 mmol), and K₂CO₃ (8.3 g, 60 mmol) were dissolved in a mixture of 200 ml of toluene and 50 ml of water and a mixed solution was stirred under reflux for 12 hours. An organic layer was extracted therefrom with chloroform and washed with water. Moisture was removed therefrom with anhydrous magnesium sulfate, and a resulting product was filtered through a filter, and the organic solvent was distilled off under reduced pressure, followed by column purification to obtain the ligand C (7.48 g, a yield: 91%).

### Preparation of Iridium Compound 9

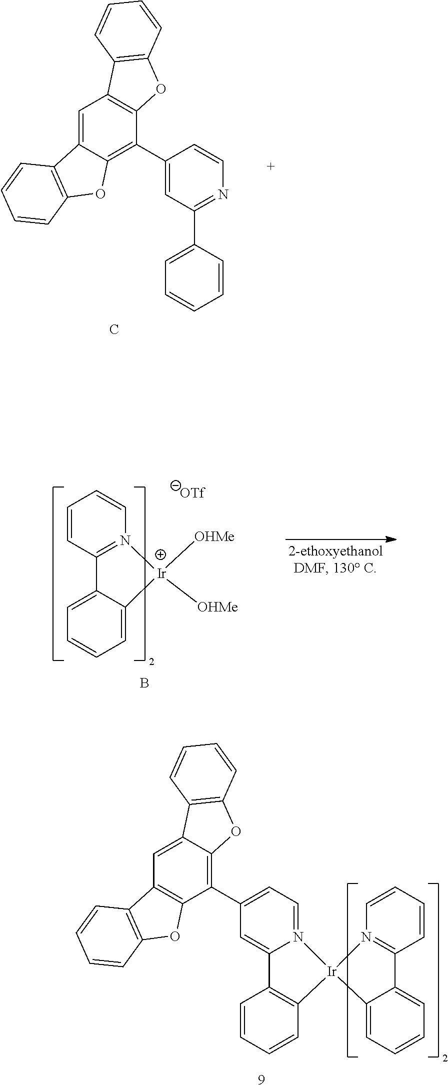

The iridium precursor B (2.15 g. 3.5 mmol) and the ligand C (1.44 g, 3 mmol) were dissolved in a mixed solvent (2-ethoxyethanol: DMF=40 ml: 40 ml) in a 100 ml round bottom flask under a nitrogen atmosphere, and a mixed solution was stirred at 130 degrees C. for 48 hours for reaction. After the reaction was completed, an organic layer was extracted therefrom with dichloromethane and distilled water, and the solvent was removed via distillation under reduced pressure. A crude product was subjected to column chromatography with toluene: hexane to obtain the iridium compound 9 (2.48 g, a yield: 83%).

### <Manufacturing of Organic Light-Emitting Diode>

A glass substrate having a thin film of ITO (indium tin oxide) having a thickness of 1,000 Å coated thereon was washed, followed by ultrasonic cleaning with a solvent such as isopropyl alcohol, acetone, and methanol. Then, the glass substrate was dried. Thus, an ITO transparent electrode was formed. HATCN as a hole injection material was deposited on the ITO transparent electrode in a thermal vacuum deposition manner. Thus, a hole injection layer having a thickness of 75 Å was formed. Then, TAPC as a hole transfer material was deposited on the hole injection layer in a thermal vacuum deposition manner. Thus, a hole transfer layer having a thickness of 300 Å was formed.

Then, NPB (HOMO energy level: −5.50 eV) as the first host and PTC (9-(4-(4,6-diphenyl-1,3,5-triazin-2-yl)phenyl)-9H-carbazole, HOMO energy level: −5.90 eV) as the second host were mixed with each other in a ratio of 1:1 (by weight) to produce a mixture. Then, a iridium complex (“PO-01”) having a following structure as the dopant was doped into the mixture as the host material at a doping concentration of 15%. The mixture containing the dopant doped therein was deposited on the hole transfer layer in a thermal vacuum deposition manner. Thus, the red light-emitting layer of a thickness of 300 Å was formed.

A hole scavenger layer made of the iridium compound 1 of the present disclosure was thermally-vacuum deposited on the red light-emitting layer so as to a thickness of 15 Å.

An electron transfer layer made of TPBi was thermally-vacuum deposited on the hole scavenger layer so as to have a thickness of 250 Å. Then, an electron injection layer made of BPhen+Li (Li concentration: 3%) was thermally-vacuum deposited on the electron transfer layer so as to have a thickness of 200 Å. Then, 1,000 Å thick aluminum was deposited on the electron injection layer to form a negative electrode. In this way, an organic light-emitting diode was manufactured.

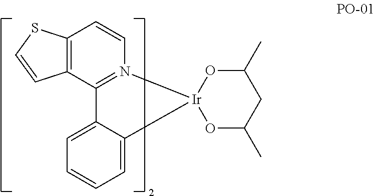

### Experimental Example

Regarding the organic light-emitting diode as described above, the operation voltage (V), the external quantum efficiency (EQE, %) at a current density of 10 mA/cm², and T95(%) as a lifespan characteristic value when being accelerated at 22.5 mA/cm² and at 40° ° C. were measured using a luminometer. In this regard, LT95 refers to a lifetime evaluation scheme and means a time it takes for an organic light-emitting diode to lose 5% of initial brightness thereof. ΔV@T95 means a difference between an initial operation voltage value and an operation voltage value at T95.

### Experimental Group 1

An organic light-emitting diode of Present Example 1-1 was manufactured in the same manner as the manner as described above in the above <Manufacturing of the organic light-emitting diode>. An organic light-emitting diode of Comparative Example 1-1 was manufactured in the same manner as the manner as described above in the above <Manufacturing of the organic light-emitting diode>except that the hole scavenger layer was absent. An organic light-emitting diode of Comparative Example 1-2 was manufactured in the same manner as the manner as described above in the above <Manufacturing of the organic light-emitting diode>except that the hole scavenger layer was present between the hole transfer layer and the light-emitting layer. This is described in a following Table 3. The organic light-emitting diode of each of Comparative Example 1-1, Comparative Example 1-2 and Present Example 1-1 was tested according to the above <Experimental Example>, and the test results are listed in a following Table 4.

TABLE 3

| | HTL | HSL | EML | HSL | ETL |
|---|---|---|---|---|---|
| Comparative | HTL | 0 Å | First host + | 0 Å | ETL |
| Example 1-1 | | | Second host + | | |
| Comparative | | 15 Å | Dopant | 0 Å | |
| Example 1-2 | | | | | |
| Present Example 1-1 | | 0 Å | | 15 Å | |

TABLE 4

| | Voltage | | Lifetime | |
|---|---|---|---|---|
| | (V) | Efficiency | (T95) | ΔV @T95 |
| Comparative | 0.00 | 100% | 100% | 0.00 |
| Example 1-1 | | | | |
| Comparative | +0.08 | 90% | 114% | −0.08 |
| Example 1-2 | | | | |
| Present Example 1-1 | +0.05 | 103% | 122% | −0.09 |

### Experimental Group 2

An organic light-emitting diode of Present Example 2-3 was manufactured in the same manner as the manner as described above in the above <Manufacturing of the organic light-emitting diode>. An organic light-emitting diode of Comparative Example 2-1 was manufactured in the same manner as the manner as described above in the above <Manufacturing of the organic light-emitting diode>except that the hole scavenger layer was absent. An organic light-emitting diode of each of Comparative Example 2-2, Comparative Example 2-3, Present Example 2-1, Present Example 2-2, and Present Example 2-4 was manufactured in the same manner as the manner as described above in the above <Manufacturing of the organic light-emitting diode>except that the thickness of the hole scavenger layer was not 15 Å but was indicated in a following Table 5. The organic light-emitting diode of each of Comparative Example 2-1, Comparative Example 2-2, Comparative Example 2-3, Present Example 2-1, Present Example 2-2, Present Example 2-3 and Present Example 2-4 was tested according to the above <Experimental Example>, and the test results are listed in the following Table 5.

TABLE 5

| | Thickness | | Voltage | Effi- | Lifetime | Δ V |
|---|---|---|---|---|---|---|
| | of HSL | | (V) | ciency | (T95) | @T95 |
| Comparative | 0 | Å | 0.00 | 100% | 100% | 0.00 |
| Example 2-1 | | | | | | |
| Present Example 2-1 | 5 | Å | +0.04 | 101% | 108% | −0.01 |
| Present Example 2-2 | 10 | Å | +0.04 | 103% | 129% | −0.10 |
| Present Example 2-3 | 15 | Å | +0.05 | 103% | 122% | −0.09 |
| Present Example 2-4 | 25 | Å | +0.11 | 103% | 115% | −0.01 |
| Comparative | 30 | Å | +0.14 | 103% | 96% | +0.06 |
| Example 2-2 | | | | | | |
| Comparative | 50 | Å | +0.38 | 103% | 53% | +0.17 |
| Example 2-3 | | | | | | |

### Experimental Group 3

An organic light-emitting diode (first host: NPB, HOMO: −5.50 eV, hole scavenger material: compound 1, HOMO: −5.00 eV) of Present Example 3-3 was manufactured in the same manner as the manner as described above in the above <Manufacturing of the organic light-emitting diode>. An organic light-emitting diode of Comparative Example 3-1 was manufactured in the same manner as the manner as described above in the above <Manufacturing of the organic light-emitting diode>except that the hole scavenger layer was absent. An organic light-emitting diode of each of Comparative Example 3-2 (first host: M-MTDATA, HOMO: −5.10 eV), Present Example 3-1 (first host: P3HT, HOMO: −5.20 eV) and Present Example 3-2 (first host: Rubrene, HOMO: −5.40 eV) was manufactured in the same manner as the manner as described above in the above <Manufacturing of the organic light-emitting diode>except that the HOMO energy level of the hole scavenger layer was modified as indicated in a following Table 6.

The organic light-emitting diode of each of Comparative Example 3-1, Comparative Example 3-2, Present Example 3-1, Present Example 3-2 and Present Example 3-3 was tested according to the above <Experimental Example>, and the test results are listed in a following Table 7. The first host material used in each of Comparative Example 3-2, Present Example 3-1, Present Example 3-2 and Present Example 3-3 are as follows:

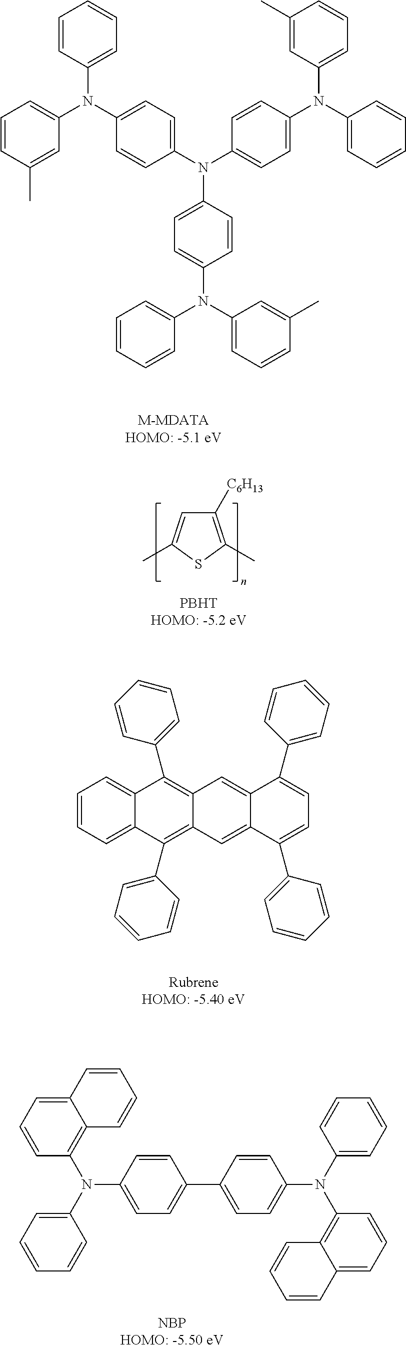

TABLE 6

| | | | Δ (\|HOMO_{(HOST-1)\|} − |
|---|---|---|---|
| | HOMO_{(HOST-1)} | HOMO_{(HSL)} | \|HOMO_{(HSL)\|}) |
| Comparative | −5.10 eV | — | — |
| Example 3-1 | | | |
| Comparative | −5.10 eV | −5.00 eV | 0.10 |
| Example 3-2 | | | |
| Present | −5.20 eV | −5.00 eV | 0.20 |
| Example 3-1 | | | |
| Present | −5.40 eV | −5.00 eV | 0.40 |
| Example 3-2 | | | |
| Present | −5.50 eV | −5.00 eV | 0.50 |
| Example 3-3 | | | |

TABLE 7

| | Voltage | | Lifetime | |
|---|---|---|---|---|
| | (V) | Efficiency | (T90) | Δ V @T90 |
| Comparative | 0.00 | 100% | 100% | 0 |
| Example 3-1 | | | | |
| Comparative | +0.03 | 101% | 99% | +0.02 |
| Example 3-2 | | | | |
| Present Example 3-1 | +0.14 | 100% | 102% | −0.10 |
| Present Example 3-2 | +0.05 | 103% | 122% | −0.09 |
| Present Example 3-3 | +0.04 | 99% | 112% | −0.10 |

### Experimental Group 4

An organic light-emitting diode (hole scavenger material: compound 1, T₁: 2.29 eV) of Present Example 4-2 was manufactured in the same manner as the manner as described above in the above <Manufacturing of the organic light-emitting diode>. An organic light-emitting diode of Comparative Example 4-1 was manufactured in the same manner as the manner as described above in the above <Manufacturing of the organic light-emitting diode>except that the hole scavenger layer was absent. An organic light-emitting diode of Present Example 4-1 (T1: 1.95 eV) was manufactured in the same manner as the manner as described above in the above <Manufacturing of the organic light-emitting diode>except that the hole scavenger layer was made of the compound 9 in place of the compound 1. An organic light-emitting diode of Present Example 4-3 (T1: 2.47 eV) was manufactured in the same manner as the manner as described above in the above <Manufacturing of the organic light-emitting diode>except that the hole scavenger layer was made of Ir(ppy)₂(acac) in place of the compound 1. This is indicated in a following Table 8. A structure of each of the hole scavenger materials as used in the Experimental Group 4 is as follows:

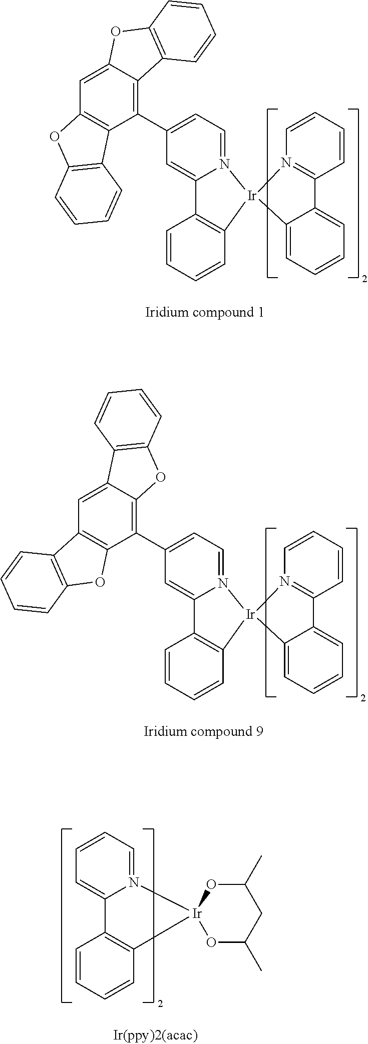

The organic light-emitting diode of each of Comparative Example 4-1, Present Example 4-1, Present Example 4-2 and Present Example 4-3 was tested according to the above <Experimental Example>, and the test results are listed in a following Table 9:

TABLE 8

| | T_{1 (DOP)} | HSL | T_{1 (HSL)} |
|---|---|---|---|
| Comparative | 2.22 eV | — | — |
| Example 4-1 | | | |
| Present Example 4-1 | | 15 Å | 1.95 eV |
| Present Example 4-2 | | 15 Å | 2.29 eV |
| Present Example 4-3 | | 15 Å | 2.47 eV |

TABLE 9

| | Voltage | | Lifetime | |
|---|---|---|---|---|
| | (V) | Efficiency | (T90) | Δ V @T90 |
| Comparative | 0 | 100% | 100% | 0 |
| Example 4-1 | | | | |
| Present Example 4-1 | +0.01 | 93% | 126% | −0.12 |
| Present Example 4-2 | +0.05 | 103% | 122% | −0.09 |
| Present Example 4-3 | +0.04 | 99% | 110% | −0.02 |

An organic light-emitting diode (dopant: PO-01, hole scavenger material: compound 1, T1: 2.29 eV) of Present Example 5-1 was manufactured in the same manner as the manner as described above in the above <Manufacturing of the organic light-emitting diode>. An organic light-emitting diode of Comparative Example 5-1 was manufactured in the same manner as the manner as described above in the above <Manufacturing of the organic light-emitting diode>except that the hole scavenger layer was absent. An organic light-emitting diode of Present Example 5-2 was manufactured in the same manner as the manner as described above in the above <Manufacturing of the organic light-emitting diode>only except that Ir(ppy)₂(acac) (T₁: 2.47 eV) in place of PO-01 was used as the dopant. This is indicated in a following Table 10. A structure of each of PO-01 and Ir(ppy)₂(acac) as used in the Experimental Group 5 is as follows:

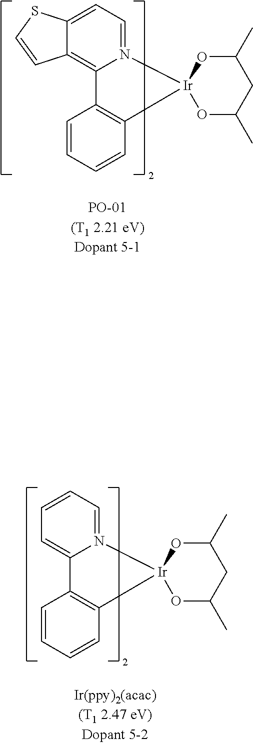

The organic light-emitting diode of each of Comparative Example 5-1, Present Example 5-1 and Present Example 5-2 was tested according to the above <Experimental Example>, and the test results are listed in a following Table 11:

TABLE 10

| | T_{1 (DOP)} | T_{1 (HSL)} |
|---|---|---|
| Comparative | −2.22 eV | — |
| Example 5-1 | | |
| Present Example 5-1 | −2.22 eV | −2.29 eV |
| Present Example 5-2 | −2.37 eV | |

TABLE 11

| | Voltage | | Lifetime | |
|---|---|---|---|---|
| | (V) | Efficiency | (T90) | Δ V @T90 |
| Comparative | 0.00 | 100% | 100% | 0 |
| Example 5-1 | | | | |
| Present Example 5-1 | +0.05 | 103% | 122% | −0.09 |
| Present Example 5-2 | +0.04 | 96% | 114% | −0.09 |

A scope of protection of the present disclosure should be construed by the scope of the claims, and all technical ideas within the scope equivalent thereto should be construed as being included in the scope of the present disclosure. Although the embodiments of the present disclosure have been described in more detail with reference to the accompanying drawings, the present disclosure is not necessarily limited to these embodiments. The present disclosure may be implemented in various modified manners within the scope not departing from the technical idea of the present disclosure. Accordingly, the embodiments disclosed in the present disclosure are not intended to limit the technical idea of the present disclosure, but to describe the present disclosure, the scope of the technical idea of the present disclosure is not limited by the embodiments. Therefore, it should be understood that the embodiments as described above are illustrative and non-limiting in all respects.

What is claimed is:

1. An organic light-emitting diode comprising:
a first electrode;
a second electrode facing the first electrode; and
an organic layer between the first electrode and the second electrode, the organic layer including a hole transfer layer, a light-emitting layer, a hole scavenger layer, and an electron transfer layer,
wherein the hole scavenger layer is between the light-emitting layer and the electron transfer layer,
wherein the light-emitting layer includes a first host, a second host, and a dopant,
wherein the electron transfer layer includes an electron transfer material,
wherein the hole scavenger layer includes a hole scavenger material,
wherein a following condition (1) is satisfied:
$$\vert {HOMO}_{( HSL )} \vert \leq \vert {HOMO}_{( HOST - 1 )} \vert \leq \vert {HOMO}_{( HOST - 2 )} \vert \leq \vert {HOMO}_{( ETL )} \vert \qquad condition ( 1 )$$
where in the condition (1), HOMO_{(HSL)} denotes a highest occupied molecular orbital (HOMO) energy level of the hole scavenger material,
HOMO_{(ETL)} denotes a HOMO energy level of the electron transfer material,
HOMO_{(HOST-1)} denotes a HOMO energy level of the first host of the light-emitting layer,
HOMO_{(HOST-2)} denotes a HOMO energy level of the second host of the light-emitting layer.

2. The organic light-emitting diode of claim 1, wherein a following condition (2) is further satisfied:
$$△ ( \vert {HOMO}_{( HOST - 1 )} \vert - \vert {HOMO}_{( HSL )} \vert ) \geq 0.15 ( eV ) . \qquad condition ( 2 )$$

3. The organic light-emitting diode of claim 1, wherein the hole transfer layer, the light-emitting layer, the hole scavenger layer, and the electron transfer layer are stacked sequentially in a direction from the first electrode to the second electrode.

4. The organic light-emitting diode of claim 1, wherein a thickness of the hole scavenger layer is greater than 0 Å and less than 30 Å.

5. The organic light-emitting diode of claim 1, wherein the light-emitting layer is a red light-emitting layer.

6. The organic light-emitting diode of claim 1, wherein a following condition (3) is further satisfied:
$$\vert {T}_{1 ( DOP )} \vert \leq \vert {T}_{1 ( HSL )} \vert \qquad condition ( 3 )$$
where in the condition (3), T₁ (DOP) denotes a triplet energy level of the dopant of the light-emitting layer and T₁ (HSL) denotes a triplet energy level of the hole scavenger material.

7. The organic light-emitting diode of claim 6, wherein |T_{1 (DOP)}| is in a range of 1.8 to 2.6 (eV).

8. The organic light-emitting diode of claim 1, wherein |HOMO_{(HOST-1)}| is in a range of 5.0 to 6.0 (eV), and |HOMO_{(HOST-2)}| is in a range of 5.2 to 6.2 (eV).

9. The organic light-emitting diode of claim 1, wherein |HOMO_{(HSL)}| is in a range of 4.5 to 5.5 (eV).

10. The organic light-emitting diode of claim 1, wherein |HOMO_{(ETL)}| is in a range of 5.4 to 6.4 (eV).

11. The organic light-emitting diode of claim 1, wherein the first host includes at least one selected from a group consisting of a tertiary amine compound, and a compound containing a carbazole group.

12. The organic light-emitting diode of claim 1, wherein the second host includes at least one selected from a group consisting of a compound containing a pyridine group, a compound containing a pyrimidine group, a compound containing a triazine group, and a compound containing a quinazoline group.

13. The organic light-emitting diode of claim 1, wherein the hole scavenger material includes an iridium complex compound represented by a following Chemical Formula 1: 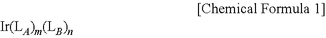
wherein in the Chemical Formula 1, L_{A} is a main ligand, and L_{B} is an ancillary ligand,
wherein L_{A} is represented by at least one selected from a group consisting of following Chemical Formula 2-1, Chemical Formula 2-2, and Chemical Formula 2-3: 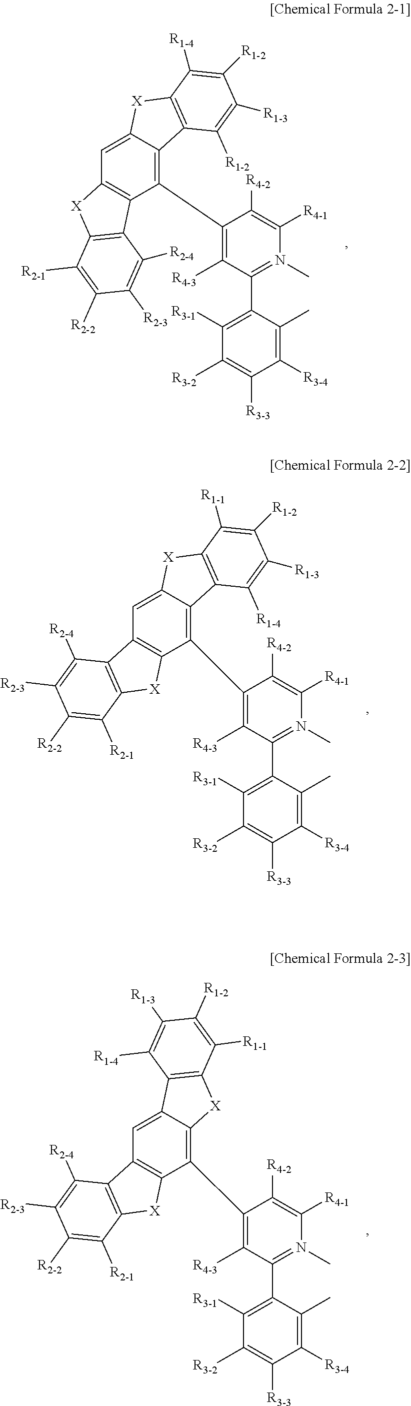
wherein L_{B} is represented by a following Chemical Formula 3: 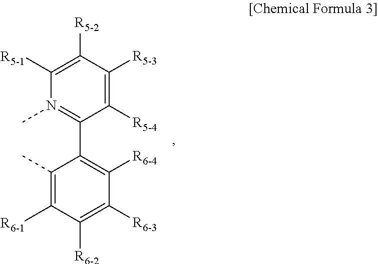
wherein in each of the Chemical Formulas 2-1 to 2-3,
each X independently represents one selected from a group consisting of O, S, NR₇ and C(R₈)(R₉),
each of R₇, R₈, and R₉ independently represents one selected from a group consisting of C1 to C30 alkyl, C3 to C30 cycloalkyl, C1 to C30 heteroalkyl, C7 to C30 arylalkyl, C1 to C30 alkoxy, C6 to C30 aryloxy, amino, silyl, C2 to C30 alkenyl, C3 to C30 cycloalkenyl, C3 to C30 heteroalkenyl, C2 to C30 alkynyl, C6 to C40 aryl, C3 to C40 heteroaryl, and combinations thereof,
each of R₁₋₁, R₁₋₂, R₁₋₃, R₁₋₄, R₂₋₁, R₂₋₂, R₂₋₃, R₂₋₄, R₃₋₁, R₃₋₂, R₃₋₃, R₃₋₄, R₄₋₁, R₄₋₂ and R₄₋₃ independently represents one selected from a group consisting of hydrogen, deuterium, halide, C1 to C30 alkyl, C3 to C30 cycloalkyl, C1 to C30 heteroalkyl, C7 to C30 arylalkyl, C1 to C30 alkoxy, C6 to C30 aryloxy, amino, silyl, C2 to C30 alkenyl, C3 to C30 cycloalkenyl, C3 to C30 heteroalkenyl, C2 to C30 alkynyl, C6 to C40 aryl, C3 to C40 heteroaryl, acyl, carbonyl, carboxylic acid, ester, nitrile, isonitrile, sulfanyl, sulfinyl, sulfonyl, phosphino, and combinations thereof,
optionally, two adjacent substituents among R₁₋₁, R₁₋₂, R₁₋₃, R₁₋₄, R₂₋₁, R₂₋₂, R₂₋₃, R₂₋₄, R₃₋₁, R₃₋₂, R₃₋₃, R₃₋₄, R₄₋₁, R₄₋₂ and R₄₋₃ are connected to each other to form one ring structure selected from a group consisting of a substituted or unsubstituted C3 to C20 cycloalkyl group, a substituted or unsubstituted C2 to C20 heterocycloalkyl group, a substituted or unsubstituted C7 to C20 arylalkyl group, a substituted or unsubstituted C2 to C20 heteroarylalkyl group, a substituted or unsubstituted C3 to C20 cycloalkenyl group, a substituted or unsubstituted C6 to C30 aryl group, and a substituted or unsubstituted C3 to C30 heteroaryl group,
wherein in the Chemical Formula 3,
each of R₅₋₁, R₅₋₂, R₅₋₃, R₅₋₄, R₆₋₁, R₆₋₂, R₆₋₃ and R₆₋₄ independently represents one selected from a group consisting of hydrogen, deuterium, a C1 to C5 linear alkyl group, and a C1 to C5 branched alkyl group, wherein the C1 to C5 linear alkyl group or C1 to C5 branched alkyl group is unsubstituted or substituted with at least one selected from deuterium and a halogen element,
optionally, two adjacent substituents among R₅₋₁, R₅₋₂, R₅₋₃, R₅₋₄, R₆₋₁, R₆₋₂, R₆₋₃ and R₆₋₄ are connected to each other to form one ring structure selected from a group consisting of a substituted or unsubstituted C3 to C20 cycloalkyl group, a substituted or unsubstituted C2 to C20 heterocycloalkyl group, a substituted or unsubstituted C7 to C20 arylalkyl group, a substituted or unsubstituted C2 to C20 heteroarylalkyl group, a substituted or unsubstituted C3 to C20 cycloalkenyl group, a substituted or unsubstituted C6 to C30 aryl group, and a substituted or unsubstituted C3 to C30 heteroaryl group, and
m is 1, 2 or 3, n is 0, 1 or 2, and a sum of m and n is 3.

14. The organic light-emitting diode of claim 13, wherein the compound represented by the Chemical Formula 1 includes at least one selected from a group consisting of following compounds 1 to 38:

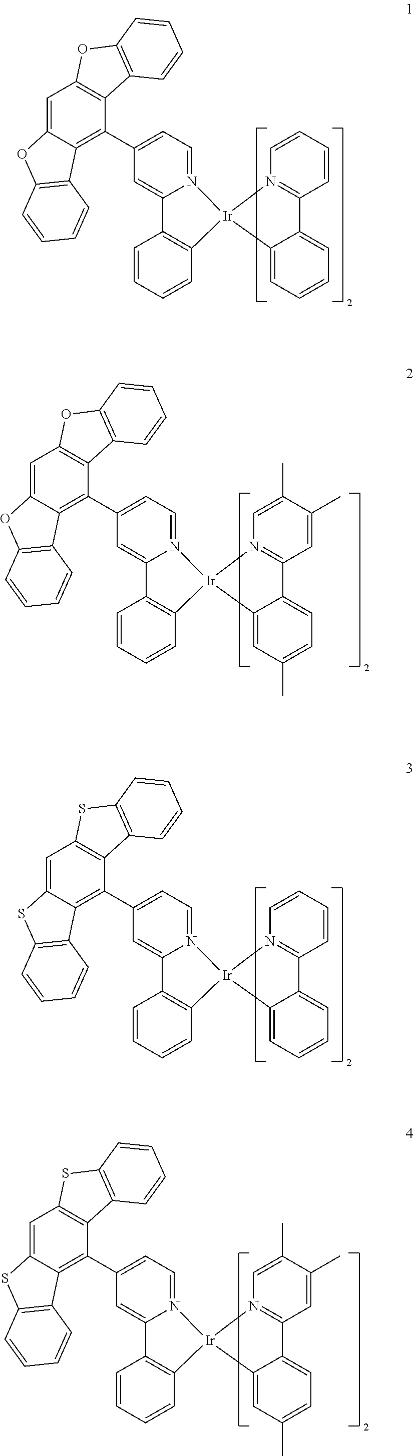

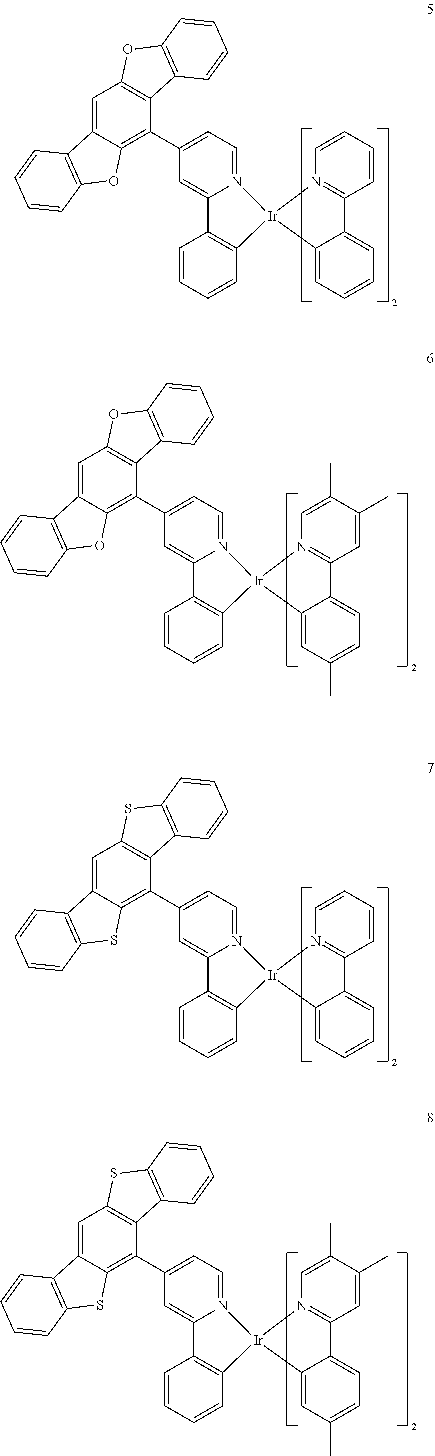

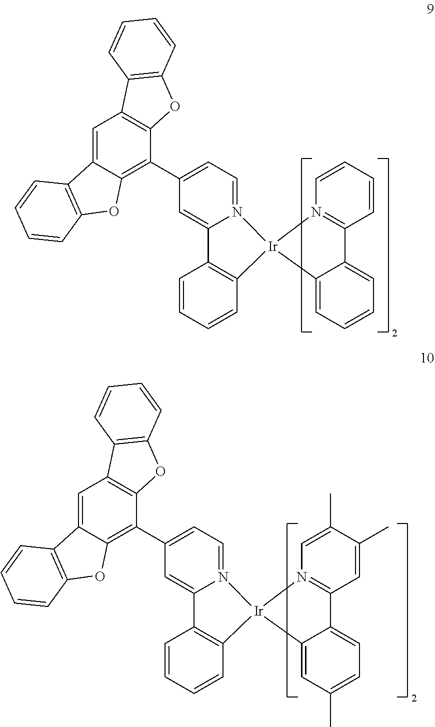

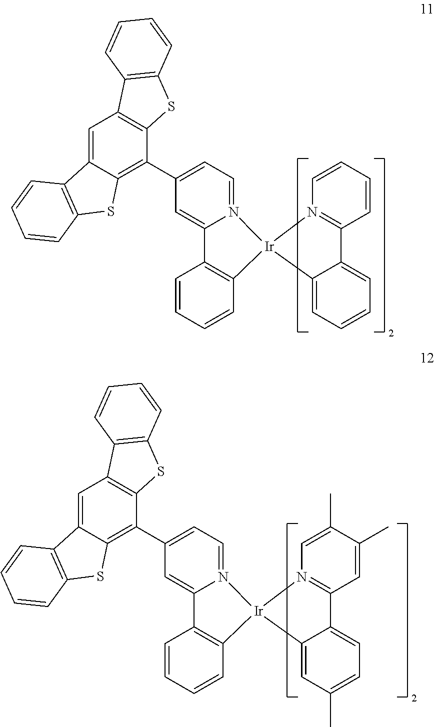

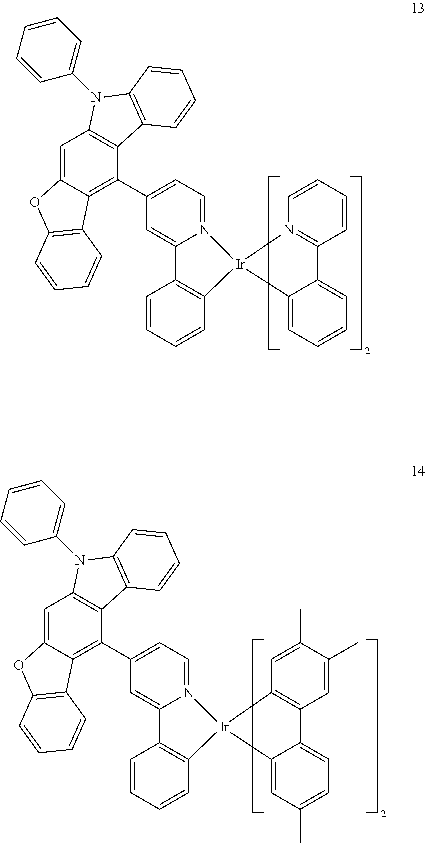

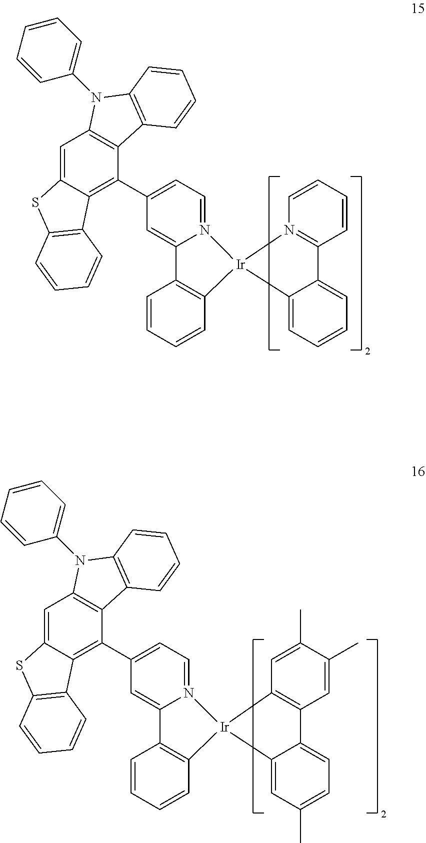

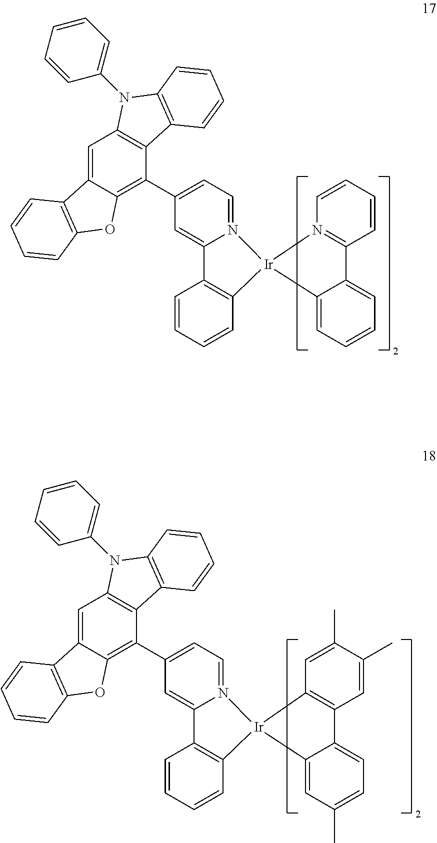

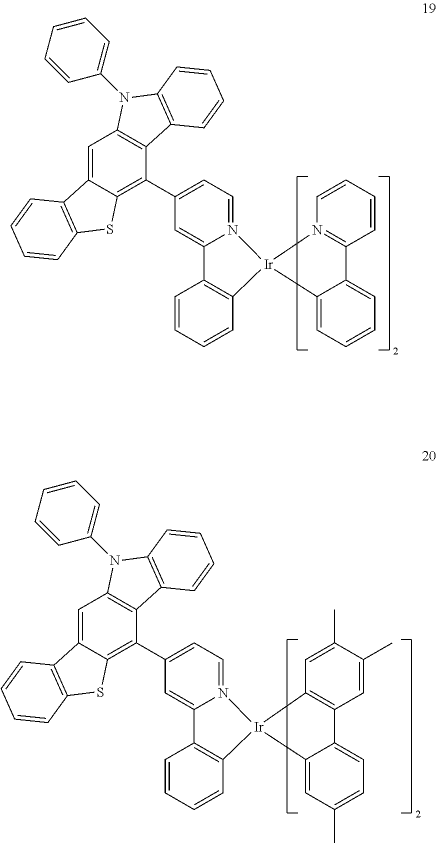

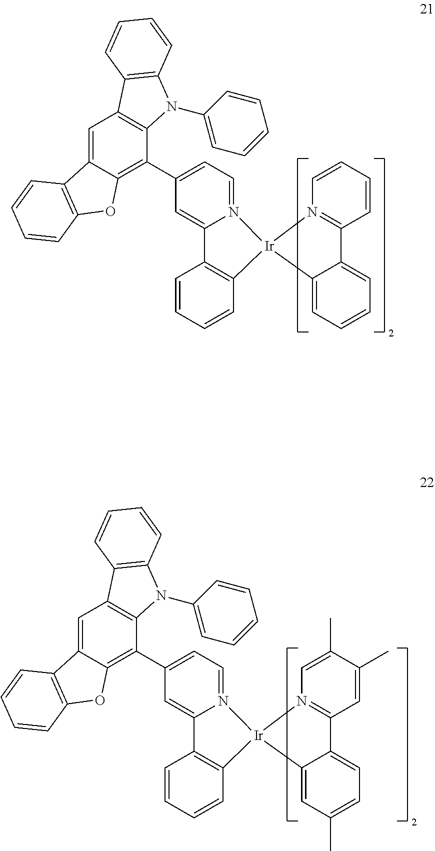

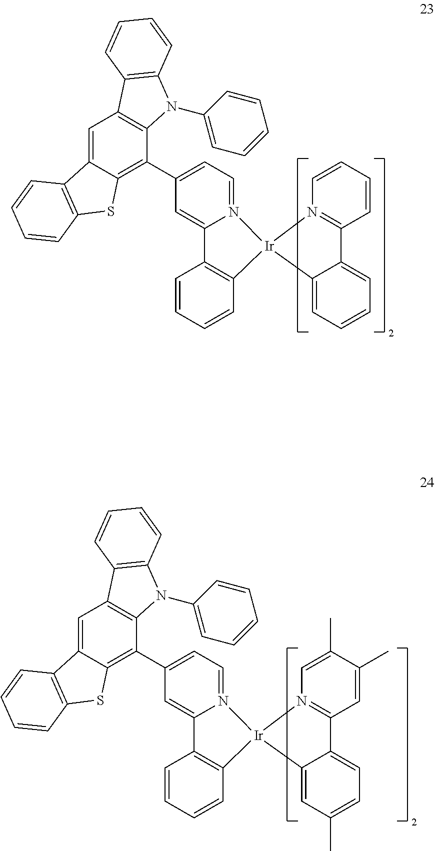

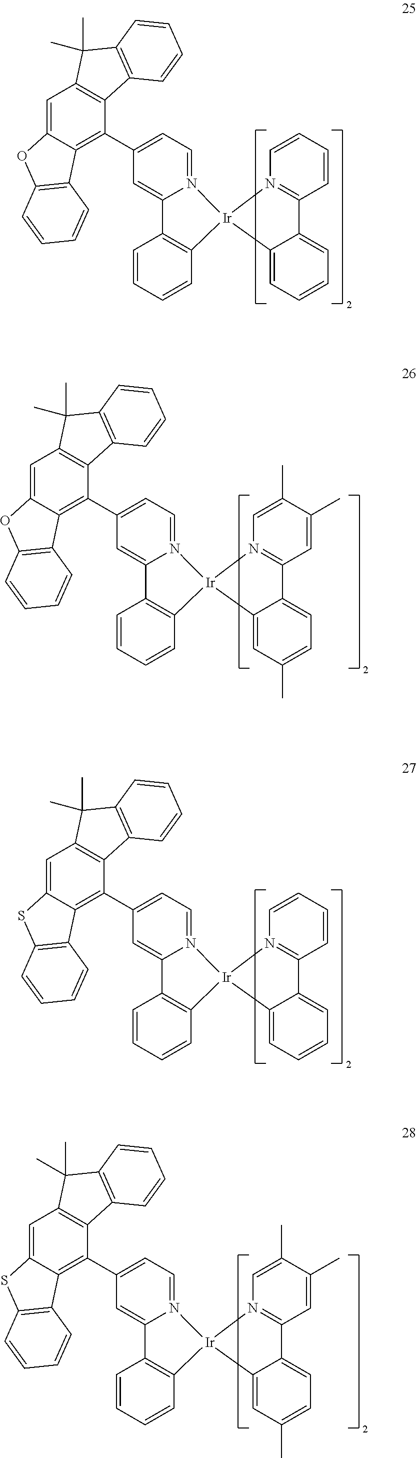

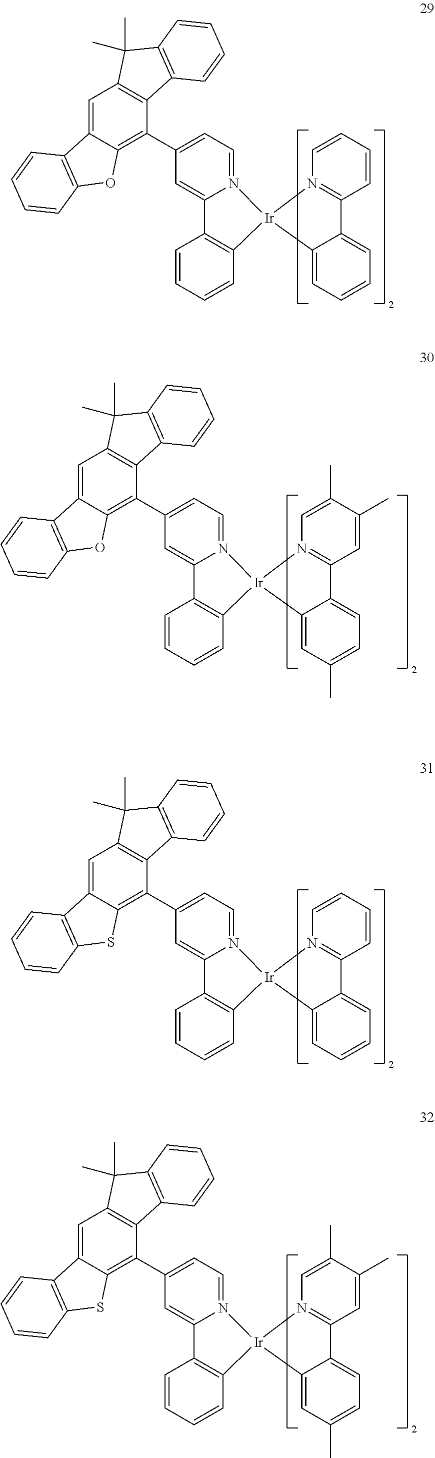

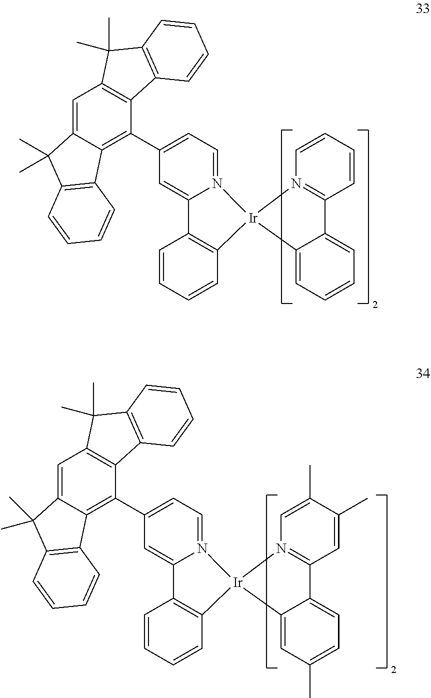

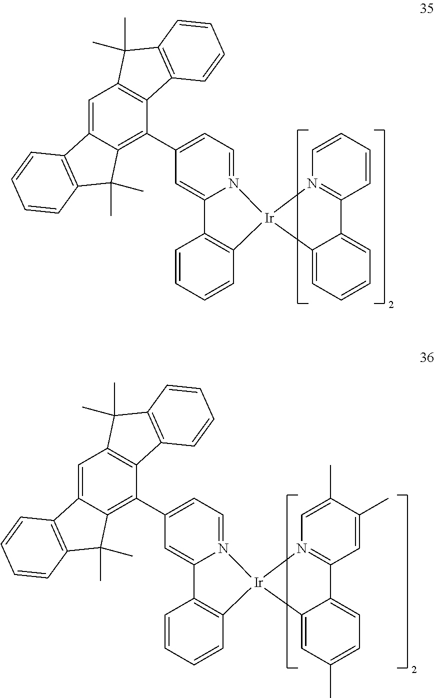

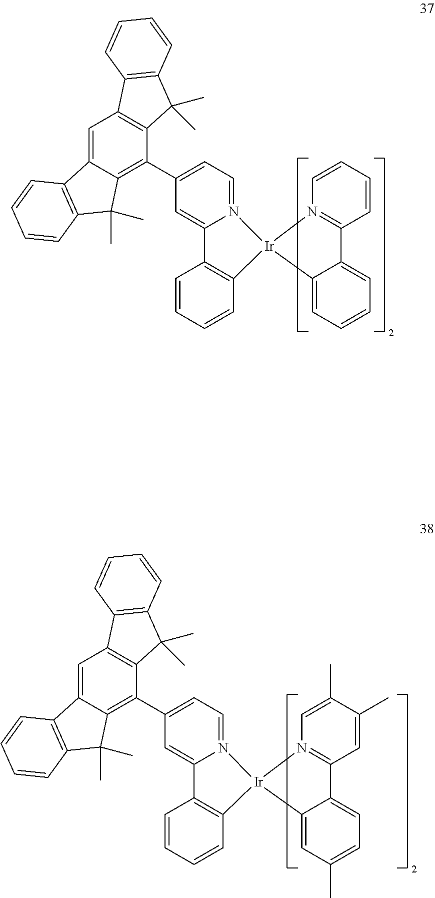

15. The organic light-emitting diode of claim 1, wherein a doping concentration of the dopant is in a range of 1% to 30% by weight based on a total weight of the first host and the second host.

16. The organic light-emitting diode of claim 1, wherein the organic layer further includes at least one selected from a group consisting of a hole injection layer and an electron injection layer.

17. An organic light-emitting display device comprising:
a substrate;
a driving element on the substrate; and
the organic light-emitting diode according to claim 1 on the substrate and connected to the driving element.
